(19) United States
(12) Patent Application Publication
(10) Pub. No.: US 2025/0330103 A1
(43) Pub. Date: Oct. 23, 2025

(54) SEMICONDUCTOR MEMS STRUCTURE AND METHOD FOR FORMING THE SAME

(71) Applicant: Taiwan Semiconductor Manufacturing Company, Ltd., Hsinchu (TW)

(72) Inventor: Yu-Hsun Li, Yunlin County (TW)

(21) Appl. No.: 18/768,150

(22) Filed: Jul. 10, 2024

Related U.S. Application Data
(60) Provisional application No. 63/636,905, filed on Apr. 22, 2024.

(51) Int. Cl. H02N 1/00

(52) U.S. Cl. CPC H02N 1/008

(57) ABSTRACT

The present disclosure, in some embodiments, relates to a MEMS (Microelectromechanical systems) structure. The MEMS structure includes a first comb structure having a first plurality of comb fingers extending outward from a first branch. A second comb structure has a second plurality of comb fingers extending outward from a second branch. The first plurality of comb fingers are laterally interleaved between the second plurality of comb fingers. The first plurality of comb fingers respectively include a weighted core material and one or more peripheral materials. The weighted core material has a larger density than the one or more peripheral materials.

### REFERENCE TO RELATED APPLICATION

This Application claims the benefit of U.S. Provisional Application No. 63/636,905, filed on Apr. 22, 2024, the contents of which are incorporated herein by reference in their entirety.

### BACKGROUND

Microelectromechanical systems, or MEMS, is a technology that integrates miniaturized mechanical and electro-mechanical elements on an integrated chip. MEMS devices are often made using micro-fabrication techniques. In recent years, MEMS devices have found a wide range of applications. For example, MEMS devices are found in hand-held devices (e.g., accelerometers, gyroscopes, digital compasses), pressure sensors (e.g., crash sensors), micro-fluidic elements (e.g., valves, pumps), optical switches (e.g., mirrors), etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate some embodiments of a MEMS (Microelectromechanical systems) structure having a weighted comb-drive actuator.

FIGS. 2A-2B illustrate some additional embodiments of a MEMS structure having a weighted comb-drive actuator.

FIGS. 3A-3B illustrate cross-sectional views of some additional embodiments of MEMS structures having a weighted comb-drive actuator.

FIGS. 4A-4C illustrate some additional embodiments of a MEMS structure having a weighted comb-drive actuator.

FIGS. 5A-5B illustrate some additional embodiments of a MEMS structure having a weighted comb-drive actuator.

FIGS. 6A-6C illustrate cross-sectional views of some additional embodiments of MEMS structures having a weighted comb-drive actuator.

FIGS. 7A-7B illustrate some additional embodiments of a comb region of a disclosed MEMS structure.

FIGS. 8A-8D illustrate some additional embodiments of a MEMS structure having a weighted comb-drive actuator.

FIGS. 8E-8F illustrate top-views of some alternative embodiments of MEMS structure having a weighted comb-drive actuator.

FIGS. 9-26 illustrate cross-sectional views of some embodiments of a method of forming a MEMS structure having a weighted comb-drive actuator.

FIGS. 27-44 illustrate cross-sectional views of some additional embodiments of a method of forming a MEMS structure having a weighted comb-drive actuator.

FIGS. 45-60 illustrate cross-sectional views of some additional embodiments of a method of forming a MEMS structure having a weighted comb-drive actuator.

FIGS. 61-76 illustrate cross-sectional views of some additional embodiments of a method of forming a MEMS structure having a weighted comb-drive actuator.

FIG. 77 illustrates a flow diagram of some embodiments of a method of forming a MEMS structure having a weighted comb-drive actuator.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many modern-day cameras use image sensors to convert light to electrical signals. Such image sensors are typically disposed within pixel regions arranged in an array. The pixel regions are respectively configured to receive incident radiation, and based upon the received radiation a camera can capture a corresponding image. However, the movement of a camera during operation can cause light that is initially incident upon one pixel region to travel to an adjacent pixel region, resulting in blurring of an image. As the resolutions of cameras increase the sizes of pixel regions within the cameras decrease, making blurring caused by movement (e.g., hand jitter) more evident in captured images.

Image stabilization technology is a technology that reduces blurring associated with a motion of an image sensor during exposure. Optical image stabilization (OIS) is one form of image stabilization technology that can be used to mitigate blurring due to involuntary camera movement (e.g., camera shaking). OIS senses a movement of a camera and subsequently compensates for the movement by controlling an optical path between a target and an image sensor. Some cameras may comprise OIS systems having an image sensor integrated chip (IC) disposed on a MEMS actuator. The MEMS actuator may comprise a comb-drive actuator that is configured to move the image sensor IC in a manner that compensates for movement of the camera to help light to consistently arrive at a same pixel region of an image sensor even when movement occurs.

For example, an optical image stabilization (OIS) system may use sensors to detect movement of an image sensor IC (e.g., pan, tilt, vibrations, etc.). If vibrations are detected, the OIS system may generate a signal that is fed into a comb-drive actuator. The signal causes the comb-drive actuator to vibrate in an opposite direction as the detected vibration so as to stabilize the image sensor and improve an image clarity. However, it has been appreciated that during extreme movements of a camera, vibrations affecting an image sensor IC may be large and difficult to account for with current MEMS actuators. Therefore, to account for such large vibrations, an actuator that has both strong and stable vibrations is desirable.

The present disclosure relates to a MEMS (microelectromechanical systems) structure having a comb-drive actuator with a plurality of comb fingers that are respectively weighted to have a relatively large weight. In some embodiments, the plurality of comb fingers may respectively include both a core material and a weighted core material. The weighted core material has a greater density than the core material, so as to increase an overall mass (e.g., weight) of the plurality of comb fingers. The increased mass of the plurality of comb fingers increases an inertia of the plurality of comb fingers during movement, thereby allowing the plurality of comb fingers to vibrate with a relatively large amplitude and/or in a stable manner that can improve a performance of the comb-drive actuator.

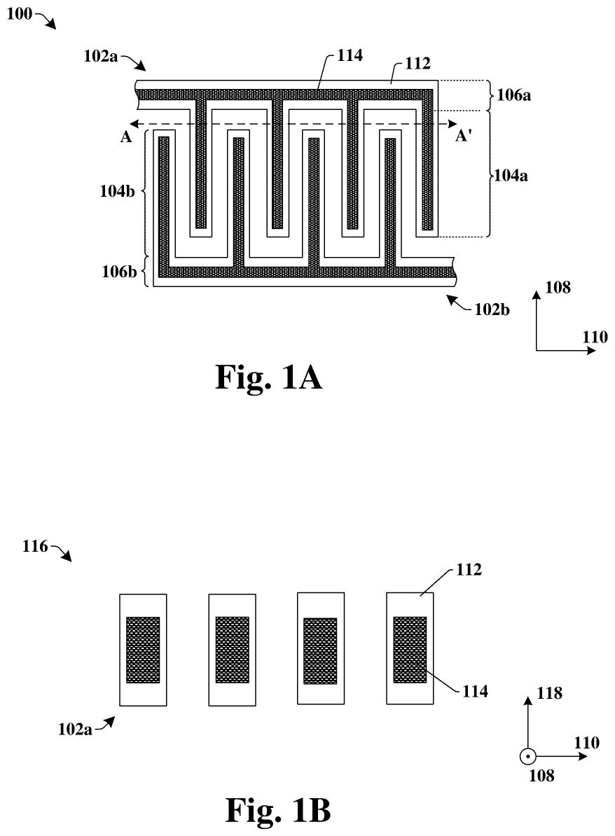

FIG. 1A illustrates a top-view of some embodiments of a MEMS structure 100 having a weighted comb-drive actuator.

The MEMS structure 100 comprises a first comb structure 102a and a second comb structure 102b. The first comb structure 102a is separated from the second comb structure 102b along a first direction 108 and along a second direction 110 that is perpendicular to the first direction 108. The first comb structure 102a comprises a first plurality of comb fingers 104a extending along the first direction 108 outward from a first branch 106a that extends along the second direction 110. The second comb structure 102b comprises a second plurality of comb fingers 104b extending along the first direction 108 outward from a second branch 106b that extends along the second direction 110. The first plurality of comb fingers 104a are interleaved between the second plurality of comb fingers 104b along the second direction 110.

The first plurality of comb fingers 104a and/or the second plurality of comb fingers 104b comprise one or more peripheral materials 112 surrounding a weighted core material 114. The weighted core material 114 has a greater density and/or weight than respective ones of the one or more peripheral materials 112. In some embodiments, a ratio of the density of the weighted core material 114 to a density of one of the one or more peripheral materials 112 may be greater than approximately 5:1, greater than approximately 8:1, or other similar values. In some embodiments, the one or more peripheral materials 112 may comprise and/or be polysilicon, a dielectric, and/or the like. In some embodiments, the weighted core material 114 may comprise and/or be a metal such as tungsten, platinum, gold, tantalum, etc.

In some embodiments, the first branch 106a and/or the second branch 106b may also comprise the one or more peripheral materials 112 surrounding the weighted core material 114. In such embodiments, having the weighted core material 114 within the first branch 106a and/or the second branch 106b may further increase a stability of the movement of the first comb structure 102a and the second comb structure 102b. In other embodiments (not shown), the first branch 106a and/or the second branch 106b may not comprise the weighted core material 114, so as to mitigate capacitive coupling between the first comb structure 102a and the second comb structure 102b. In some such embodiments, the first branch 106a and/or the second branch 106b may comprise the one or more peripheral materials 112 continuously extending between opposing sides of the first branch 106a and/or the second branch 106b.

FIG. 1B illustrates a cross-sectional view 116 of the first comb structure 102a (e.g., taken along cross-sectional line A-A′ of FIG. 1A). As shown in the cross-sectional view 116, the one or more peripheral materials 112 cover one or more sides of the weighted core material 114. In some embodiments, the one or more peripheral materials 112 contact the weighted core material 114 along the second direction 110 and along a third direction 118 that is perpendicular to the first direction 108 and the second direction 110. In some embodiments, the one or more peripheral materials 112 may continuously extend around an outer perimeter of the weighted core material 114 in the cross-sectional view 116. In other embodiments (not shown), the one or more peripheral materials 112 may discontinuously extend along one or more outermost edges of the weighted core material 114 in the cross-sectional view 116.

In some embodiments, the one or more peripheral materials 112 may have different thicknesses along horizontally and vertically extending surfaces of the weighted core material 114. For example, the one or more peripheral materials 112 may have a greater thickness along horizontally extending surfaces (e.g., above and below the weighted core material 114), than along vertically extending surfaces (e.g., to the right and to the left of the weighted core material 114). In other embodiments, the one or more peripheral materials 112 may have substantially equal thicknesses along horizontally and vertically extending surfaces of the weighted core material 114.

The greater density and/or weight of the weighted core material 114 provides the first plurality of comb fingers 104a and/or the second plurality of comb fingers 104b with a relatively large weight (e.g., a weight larger than a finger not having the weighted core material 114). The relatively large weight can provide the MEMS structure 100 with larger amplitude and/or more stable vibrations that can improve operation of the MEMS structure 100. For example, in some embodiments, the first plurality of comb fingers 104a and the second plurality of comb fingers 104b may move relative to one another in response to a sensed vibration of the MEMS structure 100. The larger amplitude and more stable vibrations provided by the disclosed MEMS structure 100 are able to counteract large magnitude vibrations of the MEMS structure 100.

In some embodiments, within a comb finger a ratio of a cross-sectional area of the one or more peripheral materials 112 (e.g., polysilicon) to a cross-sectional area of the weighted core material 114 (e.g., a metal such as tungsten) may be in a range of between approximately 1:2 and approximately 1:4, between approximately 1:3 and approximately 1:4, or other similar values. Having a ratio of cross-sectional areas between approximately 1:2 and approximately 1:4 provides for increased weighting of the comb fingers that improves performance of the MEMS structure 100, while mitigating capacitive coupling between the first comb structure 102a and the second comb structure 102b.

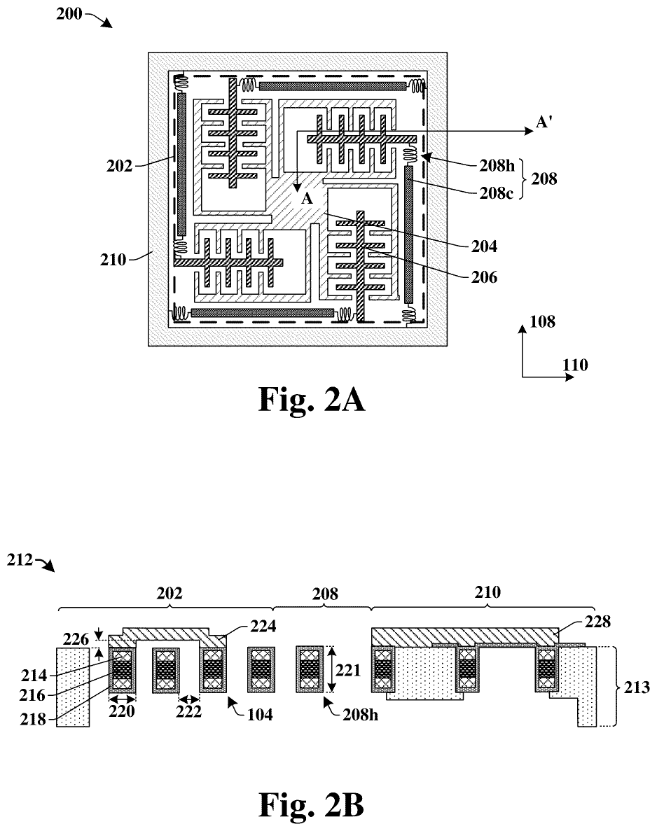

FIG. 2A illustrates a top-view of some additional embodiments of MEMS structure 200 having a weighted comb-drive actuator.

The MEMS structure 200 comprises a comb region 202 including an anchored comb segment 204 and a mobile comb segment 206 (e.g., a proof mass). The anchored comb segment 204 and the mobile comb segment 206 respectively comprise a plurality of comb fingers interleaved with one another. The mobile comb segment 206 is coupled to a frame region 210 by way of a cantilever region 208 comprising a plurality of cantilevers 208c and a plurality of hinges 208h. In some embodiments, the frame region 210 wraps around the comb region 202 in a continuous loop (e.g., an unbroken loop).

FIG. 2B illustrates a cross-sectional view 212 of some embodiments of MEMS structure (e.g., taken along cross-sectional line A-A′ FIG. 2A) having a weighted comb-drive actuator.

As shown in cross-sectional view 212, the MEMS structure comprises a substrate 213 having a comb region 202, a cantilever region 208, and a frame region 210. The MEMS structure comprises a plurality of comb fingers 104 within the comb region 202. The plurality of comb fingers 104 respectively comprise a dielectric cover 218 surrounding a core material 214 and a weighted core material 216. In some embodiments, the dielectric cover 218 continuously extends around the core material 214 and the weighted core material 216 in a closed loop.

In some embodiments, a ratio of a width 220 to a height 221 of respective ones of the plurality of comb fingers 104 may be in a range of between approximately 1:50 and approximately 1:150, in a range of between approximately 1:80 and approximately 1:120, approximately 1:100, or other similar values. In some embodiments, the plurality of comb fingers 104 may respectively have a width 220 that is greater than approximately 1 micron, approximately equal to 1.5 microns, greater than approximately equal to 1.5 microns, greater than approximately 5 microns, approximately 10 microns, greater than approximately 10 microns, or the like. In some embodiments, the plurality of comb fingers 104 may respectively have a height 221 that is approximately 100 microns, approximately 150 microns, greater than approximately 150 microns, approximately 200 microns, greater than approximately 200 microns, or other similar values.

In some embodiments, the plurality of comb fingers 104 may be separated by a distance 222 that is less than the width 220. For example, the distance 222 may be equal to approximately 5 microns, less than approximately 5 microns, or the like. In some embodiments, a ratio of the width 220 to the distance 222 is less than or equal to approximately 2:1. Having a ratio of the width 220 to the distance 222 that is less than or equal to approximately 2:1 further improves an amplitude and stability of vibrations of the MEMS structure.

In some embodiments, the dielectric cover 218 may comprise an oxide (e.g., silicon oxide), a nitride (e.g., silicon nitride), a carbide (e.g., silicon carbide), and/or the like. In some embodiments, the core material 214 may comprise a semiconductor material, such as polysilicon. In some embodiments, the weighted core material 216 may comprise a metal or a metal alloy comprising iron, cobalt, nickel, tungsten, aluminum, copper, gold, silver, and/or the like. In some embodiments (not shown), the weighted core material 216 may comprise a plurality of different metal layers. For example, the weighted core material 216 may comprise a first metal layer (e.g., comprising tungsten), a second metal layer (e.g., comprising iron), etc. In some embodiments, the second metal layer may vertically contact the first metal layer. In some additional embodiments, the second metal layer may both laterally and vertically contact the first metal layer.

In some embodiments, the weighted core material 216 may have a larger density than the core material 214. For example, the weighted core material 216 may have a density that is more than approximately 500% greater than that of the core material 214. For example, in some embodiments, the core material 214 may have a density that is less than approximately 5 g/cm³, less than approximately 3 g/cm³, approximately 2.8 g/cm³, or other similar values. In some embodiments, the weighted core material 216 may have a density that is more than approximately 10 g/cm³, more than approximately 15 g/cm³, approximately 19.3 g/cm³, or other similar values.

In some embodiments, a volume of the core material 214 may be larger than a volume of the weighted core material 216 within respective ones of the plurality of comb fingers 104. In other embodiments, a volume of the core material 214 may be smaller than a volume of the weighted core material 216 within respective ones of the plurality of comb fingers 104. In some embodiments, a volume of the core material 214 may be greater than ⅓ of a volume of the weighted core material 216. A volume of the core material 214 cannot be less than approximately ⅓ of a volume of the weighted core material 216 or else a capacitance of the comb structure may be adversely affected, thereby reducing performance of the MEMS structure.

In some embodiments, a conductive cap 224 may be disposed over one or more of the plurality of comb fingers 104. The conductive cap 224 is vertically separated from the one or more fingers by a non-zero distance 226. During operation, a voltage difference may be provided between the conductive cap 224 and the one or more fingers, so as to generate vertical movement within the plurality of comb fingers 104. One or more conductive connectors 228 are also arranged within the frame region 210. In some embodiments, the conductive cap 224 and/or the one or more conductive connectors 228 may comprise a metal such as aluminum, copper, and/or the like.

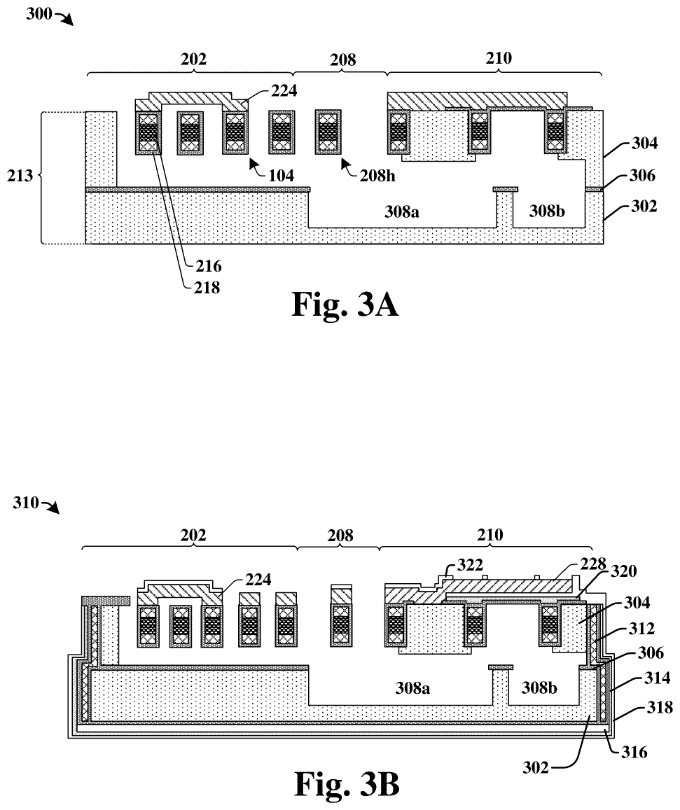

FIG. 3A illustrates a cross-sectional view of some additional embodiments of MEMS structure 300 having a weighted comb-drive actuator.

The MEMS structure 300 comprises a substrate 213 having a comb region 202, a cantilever region 208, and a frame region 210. In some embodiments, the substrate 213 includes a first semiconductor body 302 and a second semiconductor body 304 separated by a dielectric structure 306. In some embodiments, the first semiconductor body 302 comprises sidewalls forming one or more cavities 308a-308b. For example, the first semiconductor body 302 may comprise sidewalls forming a first cavity 308a within the cantilever region 208 and the frame region 210 and a second cavity 308b within the frame region 210.

FIG. 3B illustrates a cross-sectional view of some additional embodiments of MEMS structure 310 having a weighted comb-drive actuator.

The MEMS structure 300 comprises a substrate 213 having a comb region 202, a cantilever region 208, and a frame region 210. In some embodiments, the substrate 213 includes a first semiconductor body 302 and a second semiconductor body 304 separated by a dielectric structure 306. In some embodiments, the dielectric structure 306 extends from between the first semiconductor body 302 and the second semiconductor body 304 to along opposing outermost sidewalls of the first semiconductor body 302 and the second semiconductor body 304.

The dielectric structure 306 may laterally contact a peripheral core material 312 arranged along opposing sides of the first semiconductor body 302 and the second semiconductor body 304. In some embodiments, a lower dielectric 316 may be arranged below a bottom of the dielectric structure 306. In some embodiments, a peripheral first semiconductor layer 314 (e.g., comprising polysilicon) may continuously extend along outermost sidewalls of the dielectric structure 306 and below a bottom of the lower dielectric 316. In some embodiments, an additional dielectric 318 may cover opposing outermost sidewalls and a bottommost surface of the peripheral first semiconductor layer 314.

An upper semiconductor layer 320 is arranged over the dielectric cover 218 within the frame region 210. One or more conductive connectors 228 are also disposed within the frame region 210. The one or more conductive connectors 228 continuously extend from outside of the upper semiconductor layer 320 to vertically over the upper semiconductor layer 320. In some embodiments, the one or more conductive connectors 228 are vertically separated from the upper semiconductor layer 320 by the additional dielectric 318. An upper dielectric 322 is disposed over parts of the one or more conductive connectors 228 and over a conductive cap 224 within the comb region 202.

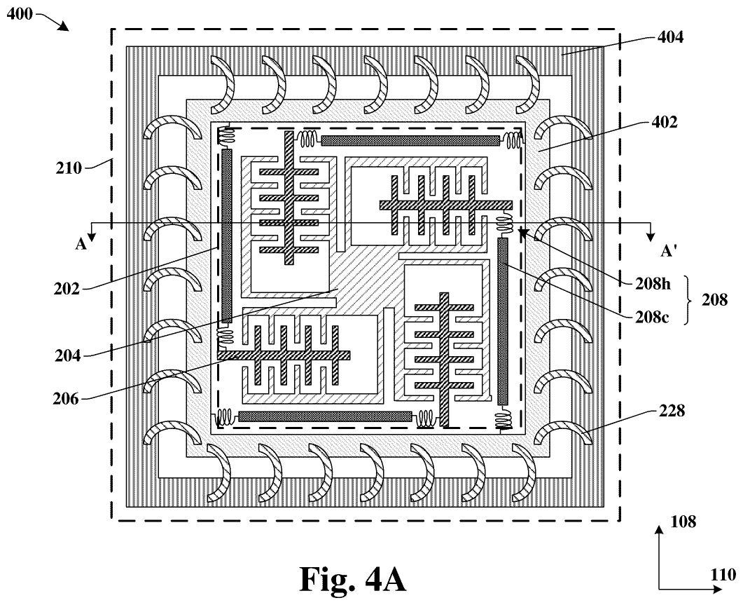

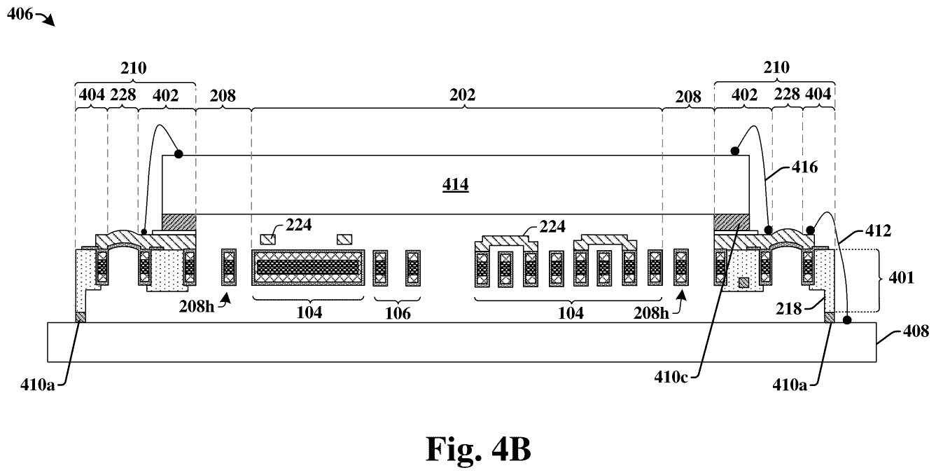

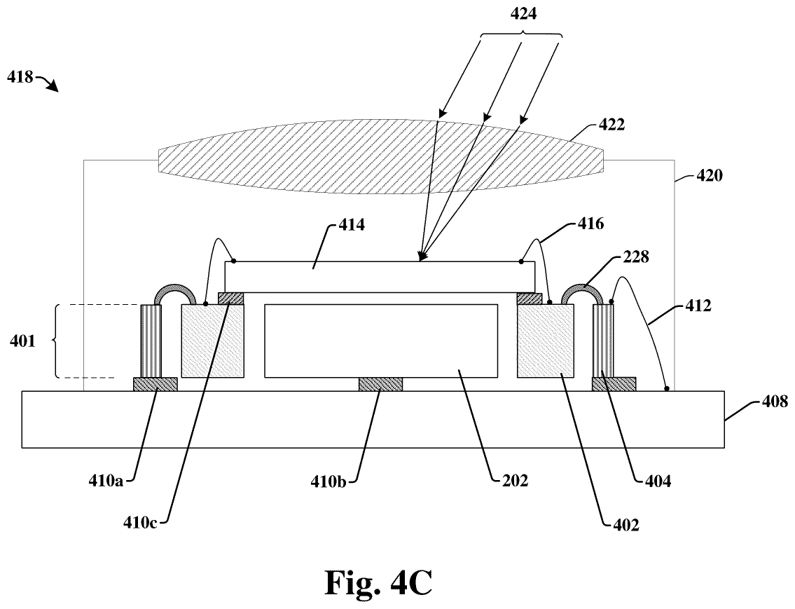

FIG. 4A illustrates a top-view of some embodiments of MEMS structure 400 having a weighted comb-drive actuator.

The MEMS structure 400 comprises a comb region 202 including an anchored comb segment 204 and a mobile comb segment 206 (e.g., a proof mass) interleaved with one another. The mobile comb segment 206 is coupled to a frame region 210 by way of a cantilever region 208 comprising a plurality of cantilevers 208c and a plurality of hinges 208h. In some embodiments, the frame region 210 wraps around the comb region 202 in a continuous and unbroken loop. In some embodiments, the frame region 210 may comprise a mid-frame 402 and an outer frame 404. The mid-frame 402 may be coupled to the mobile comb segment 206 by way of the plurality of cantilevers 208c and further coupled to the outer frame 404 by one or more conductive connectors 228.

FIG. 4B illustrates a cross-sectional view of some additional embodiments of a disclosed MEMS package 406 taken along cross-sectional line A-A′ of FIG. 4A.

The MEMS package 406 includes a MEMS structure 401 disposed on a base substrate 408. The MEMS structure 401 comprises the comb region 202, the mid-frame 402, and the outer frame 404. The mid-frame 402 is freely suspended between the comb region 202 and the outer frame 404. In some embodiments, the base substrate 410 may comprise a printed circuit board. In some embodiments, the outer frame 404 may be electrically coupled to the base substrate 408 by way of a plurality of wire bonds 412.

The outer frame 404 is fixed to the base substrate 410 by one or more first bonding structures 410a. The comb region 202 is also fixed to the base substrate 410 by one or more second bonding structures (not shown). An image sensor integrated chip 414 is coupled to the mid-frame 402. In some embodiments, the image sensor integrated chip 414 may be fixed to the mid-frame 402 by way of one or more third bonding structures 410c. The image sensor integrated chip 414 comprises one or more pixel regions respectively including an image sensing element configured to convert electromagnetic radiation (e.g., visible light, ultraviolet radiation, or the like) into an electrical signal. In some embodiments, the image sensor integrated chip 414 may comprise a CMOS (complementary metal-on-oxide) image sensor. In some embodiments, the image sensing element may comprise a photodiode, a photodetector, or the like. In some embodiments, the image sensor integrated chip 414 may be electrically coupled to the mid-frame 402 by way of a plurality of wire bonds 416.

In various embodiments, the one or more first bonding structures 410a, the one or more second bonding structures, and/or the one or more third bonding structures 410c may comprise an epoxy, a glue, conductive structures (e.g., solder bumps, vertical wire bonds, a wire stud, or the like), a polymer, and/or the like. In some additional embodiments, the one or more first bonding structures 410a, the one or more second bonding structures, and/or the one or more third bonding structures 410c may comprise a conductive structure (e.g., a vertical wire bond) surrounded by an encapsulant (e.g., an epoxy resin, an epoxy resin with filler, epoxy acrylate, a polymer, or the like).

FIG. 4C illustrates a cross-sectional view of some additional embodiments of a disclosed MEMS package 418.

The MEMS package 418 comprises a MEMS structure 401 comprising the comb region 202, the mid-frame 402, and the outer frame 404. The outer frame 404 is fixed to the base substrate 408 by one or more first bonding structures 410a. The comb region 202 is fixed to the base substrate 408 by one or more second bonding structures 410b. An image sensor integrated chip 414 is coupled to the mid-frame 402 by one or more third bonding structures 410c.

In some embodiments, the MEMS structure 401 and the image sensor integrated chip 414 are disposed within a package box (e.g., a camera module). In such embodiments, the package box comprises a housing 420 that surrounds the MEMS structure 401 and the image sensor integrated chip 414. In some embodiments, the housing 420 is attached to the base substrate 408. During operation, the mid-frame 402 is able to move relative to the comb region 202 and/or the outer frame 404. For example, unwanted movement of the package box can cause a focal point of an optical system 422 to move, thereby causing incident radiation 424 to strike different pixel regions within the image sensor integrated chip 414. The MEMS structure 401 is configured to move the image sensor integrated chip 414 in response to the unwanted movements of the package box to reduce the effects of movement on the image sensor integrated chip 414 (e.g., reduce blurring of an image by minimizing the movement of incident radiation 424 between pixels) and therefore stabilize an image being captured by the image sensor integrated chip 414. For example, when vibrations of the image sensor integrated chip 414 are detected a signal is applied to the anchored comb segment and/or the mobile comb segment. The signal vibrates the mobile comb segment and the image sensor integrated chip 414 to mitigate the effects of the vibration (e.g., in a direction opposite to the direction of the camera shake thereby stabilizing an image captured by the image sensor integrated chip 414).

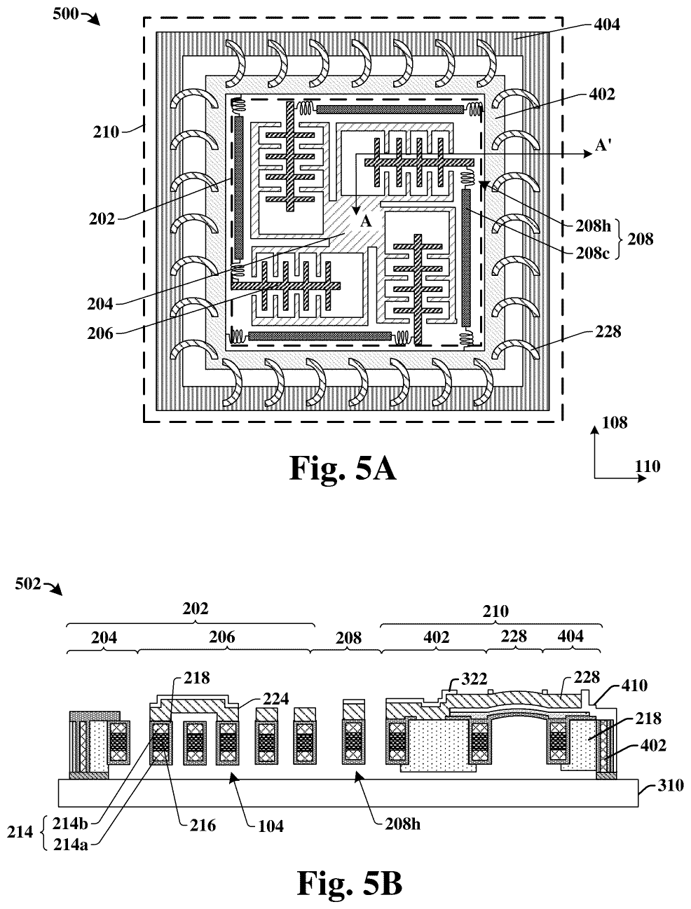

FIG. 5A illustrates a top-view of a MEMS structure 500 having a weighted comb-drive actuator.

The MEMS structure 500 comprises a comb region 202 including an anchored comb segment 204 and a mobile comb segment 206 interleaved with one another. The mobile comb segment 206 is coupled to a frame region 210 by way of a cantilever region 208 comprising a plurality of cantilevers 208c and a plurality of hinges 208h. In some embodiments, the frame region 210 wraps around the comb region 202 in a continuous and unbroken loop. In some embodiments, the frame region 210 may comprise a mid-frame 402 and an outer frame 404. The mid-frame 402 may be coupled to the mobile comb segment 206 by way of the plurality of cantilevers 208c and further coupled to the outer frame 404 by one or more conductive connectors 228.

FIG. 5B illustrates a cross-sectional view of some embodiments of a MEMS structure 502 having a weighted comb-drive actuator taken along cross-sectional line A-A′ of FIG. 5A.

The MEMS structure 502 comprises a comb region 202 having a plurality of comb fingers 104. The plurality of comb fingers 104 respectively comprise a core material 214 and a weighted core material 216. In some embodiments, the core material 214 may comprise a lower core material 214a and an upper core material 214b. The weighted core material 216 is arranged vertically between a top of the lower core material 214a and a bottom of the upper core material 214b.

A dielectric cover 218 continuously extends in a closed loop surrounding the core material 214 and the weighted core material 216. In some embodiments, the core material 214 and the weighted core material 216 may have opposing outermost sidewalls that laterally contact the dielectric cover 218. In some embodiments, the core material 214 and the weighted core material 216 may have maximum widths that are substantially equal.

A conductive cap 224 is over the plurality of comb fingers 104 and one or more conductive connectors 228 are over the frame region 210. In some embodiments, an upper dielectric 322 may be arranged over the conductive cap 224. In some embodiments, the upper dielectric 322 may also be arranged over a part, but not all, of the one or more conductive connectors 228. In such embodiments, the upper dielectric 322 has sidewalls arranged directly over the one or more conductive connectors 228.

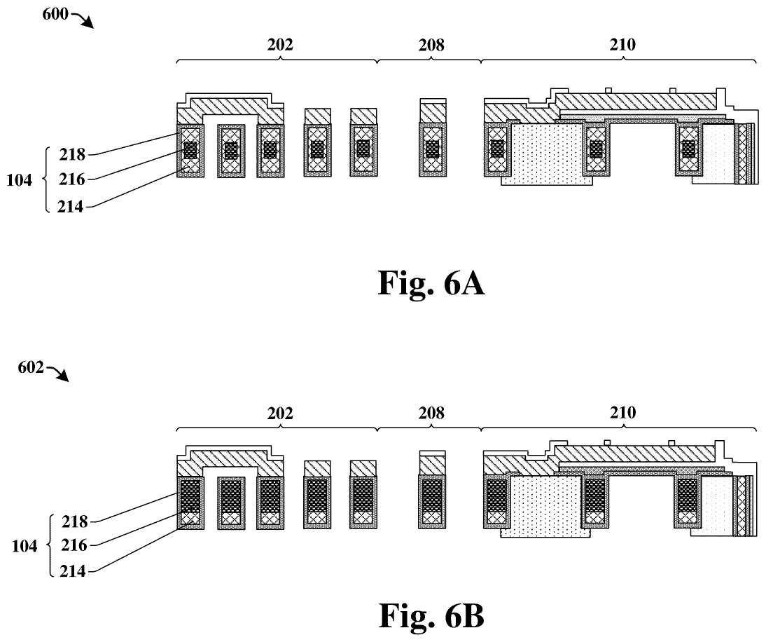

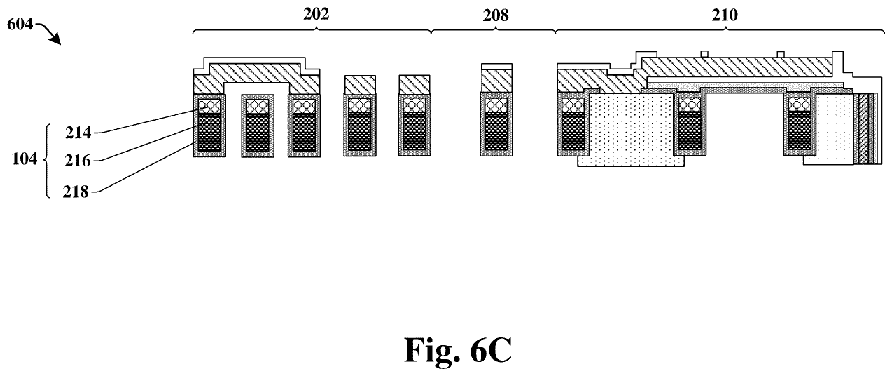

It will be appreciated that in various embodiments the disclosed core material and weighted core material may be disposed within weighted comb fingers in different configurations. FIGS. 6A-6C illustrate some embodiments of comb fingers having different configurations of weighted core material. The embodiments of FIGS. 6A-6C are not limiting embodiments, but rather are merely examples.

FIG. 6A illustrates a cross-sectional view of some embodiments of a MEMS structure 600 having a weighted comb-drive actuator.

The MEMS structure 600 comprises a comb region 202 having a plurality of comb fingers 104. The plurality of comb fingers 104 respectively comprise a core material 214 and a weighted core material 216. In some embodiments, the core material 214 may extend in a closed loop surrounding the weighted core material 216.

A dielectric cover 218 continuously extends in a closed loop surrounding the core material 214 and the weighted core material 216. In some embodiments, the core material 214 both laterally and vertically separates the weighted core material 216 from the dielectric cover 218. In some embodiments, the core material 214 has a greater maximum width than the weighted core material 216. In some embodiments, the core material 214 may have a non-uniform thickness along different edges of the weighted core material. For example, the core material 214 may have a greater thickness along opposing outermost sidewalls of the weighted core material 216 than along topmost and bottommost surfaces of the weighted core material 216.

FIG. 6B illustrates a cross-sectional view of some embodiments of a MEMS structure 602 having a weighted comb-drive actuator.

The MEMS structure 602 comprises a comb region 202 having a plurality of comb fingers 104. The plurality of comb fingers 104 respectively comprise a core material 214 and a weighted core material 216. In some embodiments, a bottommost surface of the weighted core material 216 may be arranged over a topmost surface of the core material 214. A dielectric cover 218 continuously extends in a closed loop surrounding the core material 214 and the weighted core material 216. In some embodiments, the dielectric cover 218 laterally and vertically contacts both the core material 214 and the weighted core material 216. In some embodiments, the core material 214 and the weighted core material 216 have maximum widths that are substantially equal.

FIG. 6C illustrates a cross-sectional view of some embodiments of a MEMS structure 604 having a weighted comb-drive actuator.

The MEMS structure 604 comprises a comb region 202 having a plurality of comb fingers 104. The plurality of comb fingers 104 respectively comprise a core material 214 and a weighted core material 216. In some embodiments, a bottommost surface of the core material 214 may be arranged over a topmost surface of the weighted core material 216. A dielectric cover 218 continuously extends in a closed loop surrounding the core material 214 and the weighted core material 216. In some embodiments, the dielectric cover 218 laterally and vertically contacts both the core material 214 and the weighted core material 216. In some embodiments, the core material 214 and the weighted core material 216 have maximum widths that are substantially equal.

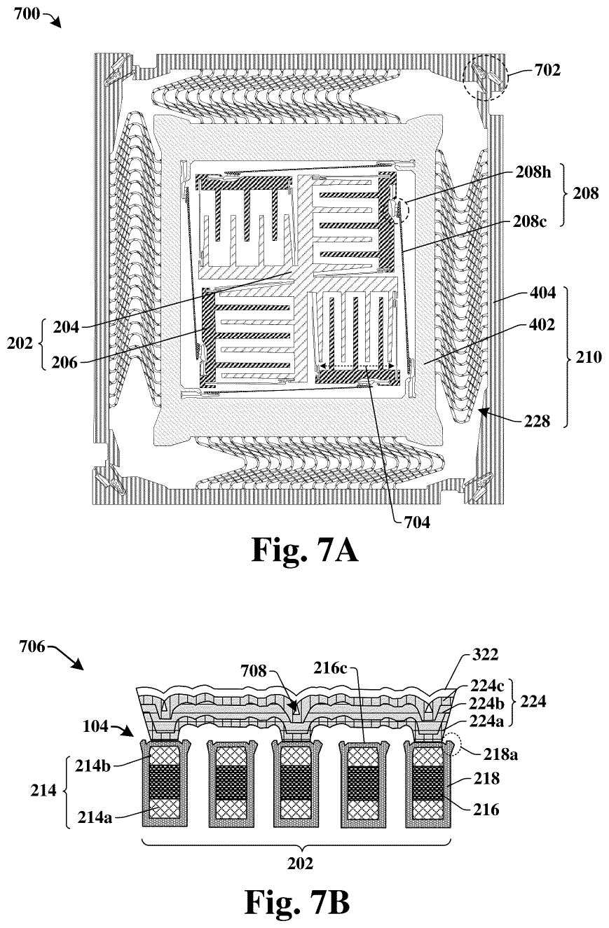

FIG. 7A illustrates a top-view of some additional embodiments of a MEMS structure 700 having a weighted comb-drive actuator.

The MEMS structure 700 comprises a frame region 210 surrounding a comb region 202 and a cantilever region 208. The frame region 210 includes a mid-frame 402 and an outer frame 404. The mid-frame 402 is coupled to the outer frame 404 by one or more conductive connectors 228.

In some embodiments, the outer frame 404 comprises a plurality of different frame segments. The plurality of different frame segments respectively include a latch 702 that connects the different frame segments of the outer frame 404. In some embodiments, the latch 702 may comprise a first outer frame segment that includes a spring-loaded segment that may be inserted into a cavity of an adjacent outer frame segment to lock the outer frame segments together in a fixed relation.

The mid-frame 402 is coupled to the comb region 202 by a cantilever 208c. In some embodiments, the cantilever 208c may comprise a hinge 208h including a shock absorption region.

FIG. 7B illustrates a cross-sectional view 706 of some additional embodiments of a comb region of a disclosed MEMS structure (e.g., taken along cross-sectional line 704 of FIG. 7A).

As shown in cross-sectional view 706, the comb region 202 comprises a plurality of comb fingers 104. The plurality of comb fingers 104 respectively comprise a dielectric cover 218 surrounding a core material 214 and a weighted core material 216. In some embodiments, the core material 214 may comprise a tapered width that increases from a top surface of the core material 214. In some other embodiments (not shown), the weighted core material 216 may comprise a tapered width that increases from a top surface of the weighted core material 216. In some embodiments, the dielectric cover 218 comprises horn segments 218a arranged along upper outer edges of the dielectric cover 218. The horn segments 218a protrude outward from an upper central surface 218c of the dielectric cover 218. In some embodiments (not shown), the finger structures in the cantilever and/or frame regions may also have horn segments.

A conductive cap 224 is over the plurality of comb fingers 104. The conductive cap 224 comprises tapered legs that contact alternating ones of the plurality of comb fingers 104. In some embodiments, the tapered legs contact the upper central surface 216c and are set back from opposing edges of the upper central surface 216c by non-zero distances. In some embodiments, an upper dielectric 322 is over the conductive cap 224.

In some embodiments, the conductive cap 224 may comprise a multi-layer structure having a plurality of layers stacked onto one another. For example, in some embodiments the conductive cap 224 may comprise a first layer 224a, a second layer 224b stacked onto the first layer 224a, and a third layer 224c stacked onto the second layer 224b. In some embodiment, the first layer 224a may comprise a metal, the second layer 224b may comprise a metal nitride, and the third layer 224c may comprise a metal. For example, the first layer 224a may comprise tantalum (Ta), the second layer 224b may comprise tantalum nitride (TaN), and the third layer 224c may comprise aluminum copper (AlCu). In some embodiments, the third layer 224c may enclose a cavity 708 that is over an underlying one of the plurality of comb fingers 104.

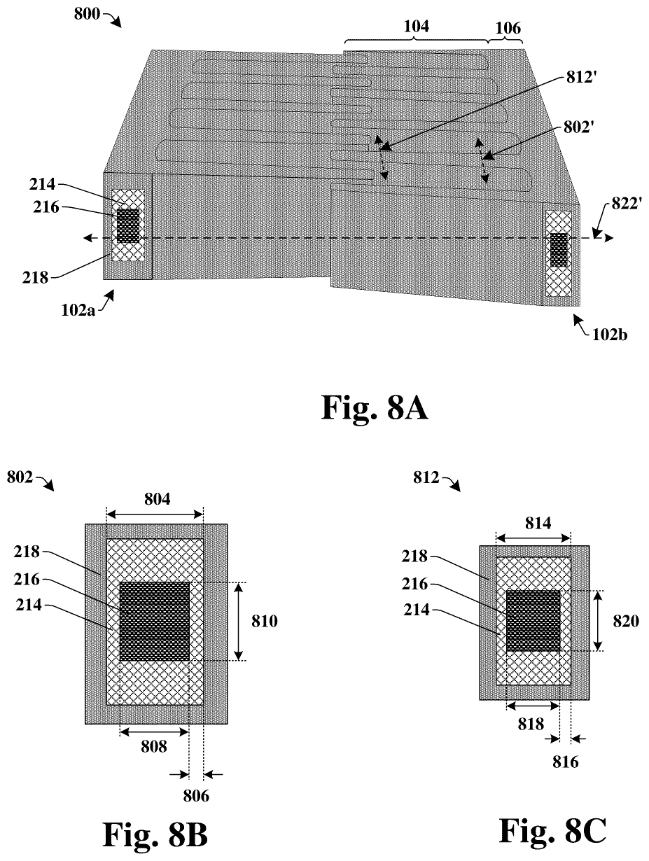

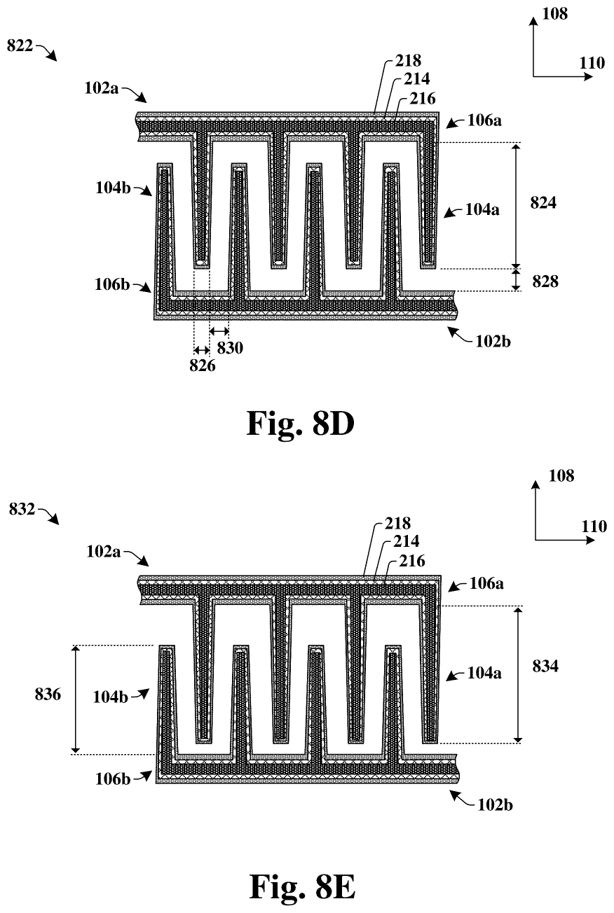

FIGS. 8A-8C illustrate some additional embodiments of a MEMS structure having a weighted comb-drive actuator.

FIG. 8A illustrates a three-dimensional view of a MEMS structure 800 comprising a first comb structure 102a and a second comb structure 102b. The first comb structure 102a and the second comb structure 102b respectively have a plurality of comb fingers 104 extending outward from a branch 106 and interleaved with one another. The plurality of comb fingers 104 respectively have a core material 214 wrapping around a weighted core material 216 and a dielectric cover 218 wrapping around the core material 214.

The plurality of comb fingers 104 respectively have a tapered width that decreases away from a connected branch 106.

FIGS. 8B-8C illustrate cross-sectional views, 802 and 812, taken at different locations along the plurality of comb fingers 104 in FIG. 8A.

FIG. 8B illustrates a cross-sectional view 802 taken at a first location 802′ along the plurality of comb fingers 104 in FIG. 8A. The core material 214 within cross-sectional view 802 has a first core material width 804 and a first core material thickness 806 along a sidewall of the weighted core material 216. The weighted core material 216 has a first weighted core material width 808 and a first weighted core material height 810.

FIG. 8C illustrates a cross-sectional view 812 taken at a second location 812′ along the plurality of comb fingers 104 in FIG. 8A. The core material 214 within cross-sectional view 812 has a second core material width 814 and a second core material thickness 816 along a sidewall of the weighted core material 216. The weighted core material 216 has a second weighted core material width 818 and a second weighted core material height 820.

Because the plurality of comb fingers have tapered widths, the first core material width 804 is smaller than the second core material width 814. For example, the first core material width 804 may be less than or equal to approximately 1 micron (m) and the second core material width 814 may be less than or equal to approximately 4 μm. The first core material thickness 806 is also smaller than the second core material thickness 816. For example, the first core material thickness 806 may be less than or equal to approximately 0.5 μm and the second core material thickness 816 may be less than or equal to approximately 3 μm. The first weighted core material width 808 is also smaller than the second weighted core material width 818. For example, the first weighted core material width 808 may be less than or equal to approximately 1 μm and the second weighted core material width 818 may be less than or equal to approximately 4 μm. The first weighted core material height 810 is also smaller than the second weighted core material height 820. For example, the first weighted core material height 810 may be less than or equal to approximately 2 μm and the second weighted core material height 820 may be less than or equal to approximately 6 μm.

FIG. 8D illustrates a top-view 822 of the MEMS structure of FIG. 8A. In some embodiments, the first plurality of comb fingers 104a and/or the second plurality of comb fingers 104b may respectively have a length 824 along a first direction 108 and a width 826 along a second direction 110. The length 824 may be in a range of between approximately 10 microns and approximately 20 microns, approximately equal to 16 microns, or other similar values. The width 826 may be in a range of between approximately 0.5 microns and approximately 2 microns, approximately equal to 1 micron, or other similar values. In some embodiments, the first comb structure 102a and/or the second comb structure 102b may be separated along the first direction 108 by a space 828 that is in a range of between approximately 2 microns and approximately 8 microns, that is approximately equal to 5 microns, or other similar values. In some embodiments, the first comb structure 102a and/or the second comb structure 102b may be separated along the second direction 110 by a space 830 that is in a range of between approximately 1 micron and approximately 2 microns, that is approximately equal to 1.6 microns, or other similar values. In some embodiments, a ratio of the length 824 to the space 828 may be in a range of between approximately 4:1 and approximately 2:1, greater than 3:1, approximately 3:1, or other similar values. In some embodiments, a ratio of the width 826 to the space 830 may be in a range of between approximately 1:1 and approximately 1:2, greater than 1:1.5, approximately 1:1.6, or other similar values.

Although the top-view 822 of FIG. 8D illustrates the first plurality of comb fingers 104a and/or the second plurality of comb fingers 104b as having equal lengths and widths, it will be appreciated that in some embodiments the first plurality of comb fingers 104a and/or the second plurality of comb fingers 104b may have different widths and/or different lengths. For example, FIG. 8E illustrates a top-view 832 of an exemplary MEM structure having a first plurality of comb fingers 104a and/or a second plurality of comb fingers 104b with different lengths. The first plurality of comb fingers 104a have a first length 834 and the second plurality of comb fingers 104b have a second length 836 that is smaller than the first length 834. FIG. 8F illustrates a top-view 838 of an exemplary MEM structure having a first plurality of comb fingers 104a and/or a second plurality of comb fingers 104b with different widths. For example, the first plurality of comb fingers 104a have a first width 840 and the second plurality of comb fingers 104b have a second width 842 that is smaller than the first width 840.

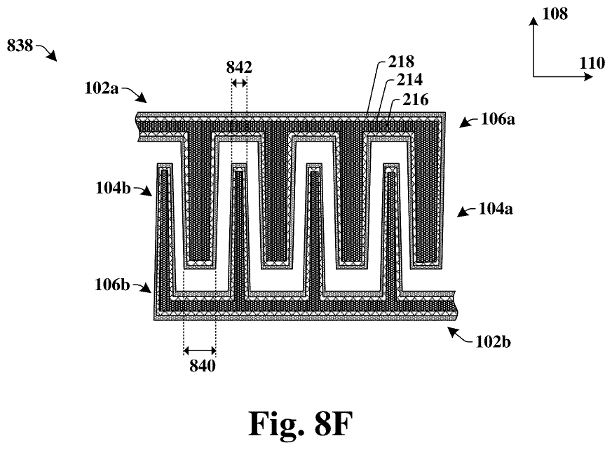

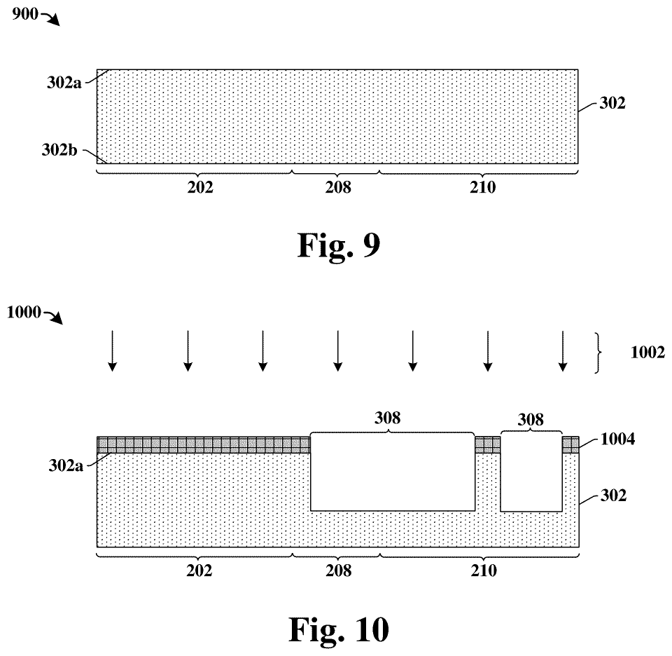

FIGS. 9-26 illustrate cross-sectional views 900-2600 of some embodiments of a method of forming a MEMS structure having a weighted comb-drive actuator. Although the cross-sectional views 900-2600 shown in FIGS. 9-26 are described with reference to a method, it will be appreciated that the structures shown in FIGS. 9-26 are not limited to the method of formation but rather may stand alone separate of the method.

As shown in cross-sectional view 900 of FIG. 9, a first semiconductor body 302 is provided. In various embodiments, the first semiconductor body 302 may be any type of substrate (e.g., silicon, SiGe, SOI, etc.), such as a semiconductor wafer, as well as any other type of semiconductor and/or epitaxial layers, associated therewith. The first semiconductor body 302 has a first side 302a and a second side 302b, which opposes the first side 302a. The first semiconductor body 302 also comprises a comb region 202, a cantilever region 208, and a frame region 210.

As shown in cross-sectional view 1000 of FIG. 10, a plurality of cavities 308 are formed within the first side 302a of the first semiconductor body 302. The plurality of cavities 308 are formed by sidewalls and a recessed surface of the first semiconductor body 302. In some embodiments, the plurality of cavities 308 may be formed by selectively exposing the first side 302a of the first semiconductor body 302 to an etchant 1002 according to a mask 1004. In some embodiments, the etchant 1002 may comprise a dry etchant (e.g., comprising fluorine, chlorine, and/or the like). In some embodiments, the mask 1004 may comprise a photosensitive material (e.g., a photoresist), a hard mask, and/or the like.

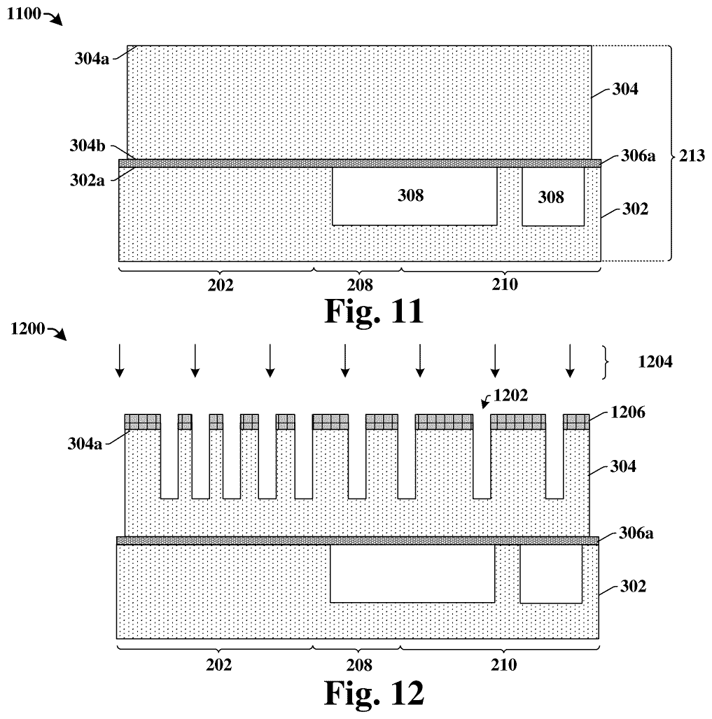

As shown in cross-sectional view 1100 of FIG. 11, the first semiconductor body 302 is bonded to a second semiconductor body 304 to form a substrate 213. The second semiconductor body 304 has a first side 304a and a second side 304b opposing the first side 304a. In some embodiments, a first dielectric layer 306a is formed along the first side 302a of the first semiconductor body 302. The first semiconductor body 302 is subsequently bonded to the second side 304b of the second semiconductor body 304 by way of the first dielectric layer 306a. In various embodiments, the second semiconductor body 304 may be any type of substrate (e.g., silicon, SiGe, SOI, etc.), such as a semiconductor wafer, as well as any other type of semiconductor and/or epitaxial layers, associated therewith.

In some embodiments, the first dielectric layer 306a may be formed by a thermal oxidation process, such as a wet thermal oxidation process or a dry thermal oxidation process. In such embodiments, the first semiconductor body 302 is placed in a furnace and heated to a temperature typically ranging between approximately 800 degrees Celsius (° C.) and approximately 1200° C. in the presence of oxygen to form the first dielectric layer 306a. In other embodiments, the first dielectric layer 306a can be formed by a spin-on process, a plasma vapor deposition (PVD) process, a chemical vapor deposition (CVD) process, an atomic layer deposition (ALD) process, or other techniques. In some embodiments, the second semiconductor body 304 is bonded to a top surface of the first dielectric layer 306a through a fusion bonding process.

As shown in cross-sectional view 1200 of FIG. 12, a plurality of trenches 1202 are formed along the first side 304a of the second semiconductor body 304. The plurality of trenches 1202 are formed by sidewalls and a recessed surface of the second semiconductor body 304. In some embodiments, the plurality of trenches 1202 may be formed by selectively exposing the first side 304a of the second semiconductor body 304 to an etchant 1204 according to a mask 1206. In some embodiments, the etchant 1204 may comprise a dry etchant (e.g., comprising fluorine, chlorine, and/or the like). In some embodiments, the mask 1206 may comprise a photosensitive material (e.g., a photoresist), a hard mask, and/or the like.

In some embodiments, the plurality of trenches 1202 may be formed to have a width of greater than approximately 5 μm, of approximately 10 μm, of greater than approximately 10 μm, or the like. In some embodiments, the plurality of trenches 1202 may be separated by a distance that is less than the width. For example, the plurality of trenches 1202 may be separated by a distance that is equal to approximately 5 μm, less than approximately 5 μm, or the like.

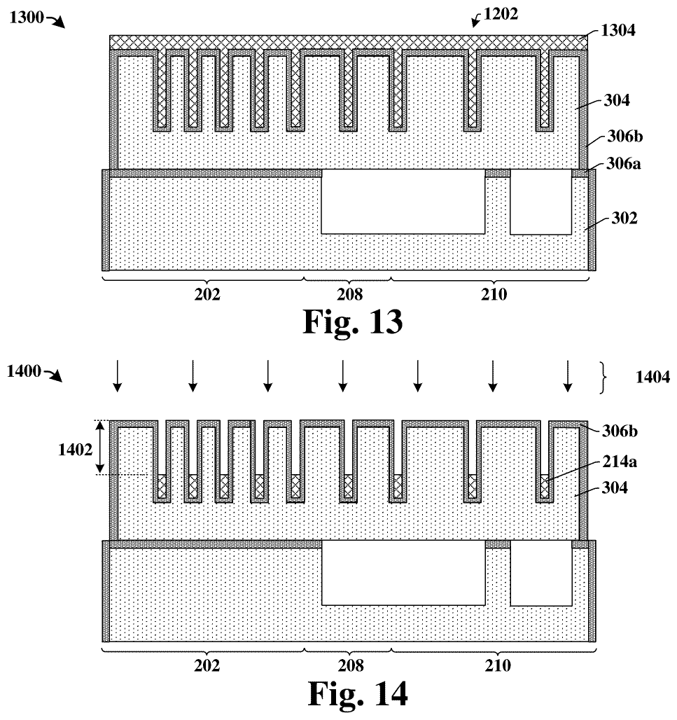

As shown in cross-sectional view 1300 of FIG. 13, a dielectric liner 306b is formed along interior surfaces of the second semiconductor body 304 that form the plurality of trenches 1202. In some embodiments, the dielectric liner 306b is formed to continuously extend from within the plurality of trenches 1202 to along opposing outermost sidewalls of the first semiconductor body 302, the first dielectric layer 306a, and/or the second semiconductor body 304.

In some embodiments, the dielectric liner 306b may comprise an oxide (e.g., silicon oxide), a nitride (e.g., silicon nitride), or the like. In some embodiments, the dielectric liner 306b may be formed by a thermal oxidation process. In such embodiments, the first semiconductor body 302 and the second semiconductor body 304 may be exposed to a high temperature (e.g., greater than or equal to approximately 700° C., greater than or equal to approximately 800° C., between approximately 900° C. and approximately 1100° C., or other similar values). In some embodiments, the first semiconductor body 302 and the second semiconductor body 304 may be exposed to the high temperature in a presence of water vapor.

A lower core material layer 1304 is subsequently formed on the dielectric liner 306b. In some embodiments, the lower core material layer 1304 may comprise a semiconductor material, such as polysilicon or the like. The lower core material layer 1304 may be formed by way of a deposition process onto the dielectric liner 306b and within the plurality of trenches 1202. In various embodiments, the deposition process may comprise a PVD process, a CVD process, a PE-CVD process, an ALD process, or the like.

As shown in cross-sectional view 1400 of FIG. 14, the lower core material layer (e.g., 1304 of FIG. 13) is recessed to form a lower core material 214a that is a non-zero distance 1402 below a top of the dielectric liner 306b. In some embodiments, the lower core material 214a may also be recessed below a top of the second semiconductor body 304. In some embodiments, the lower core material 214a may be recessed by exposing the lower core material layer (e.g., 1304 of FIG. 13) to an etchant 1404 that has a high etching selectivity. The high etching selectivity will etch the lower core material layer without significantly etching the dielectric liner 306b, so as to recess the lower core material 214a below a top of the dielectric liner 306b. In some embodiments, the etchant 1404 may comprise nitric acid, hydrofluoric acid, and/or the like.

As shown in cross-sectional view 1500 of FIG. 15, a weighted core material layer 1502 is formed onto a topmost surface of the lower core material 214a and within the plurality of trenches 1202. The weighted core material layer 1502 may comprise a metal or a metal alloy. For example, the weighted core material layer 1502 may comprise iron, cobalt, nickel, tungsten, copper, aluminum, gold, silver, and/or the like. The weighted core material layer 1502 may be formed by a deposition process (e.g., a PVD process, a CVD process, a PE-CVD process, an ALD process, sputtering, or the like) and/or a plating process (e.g., electroplating, electro-less plating, etc.).

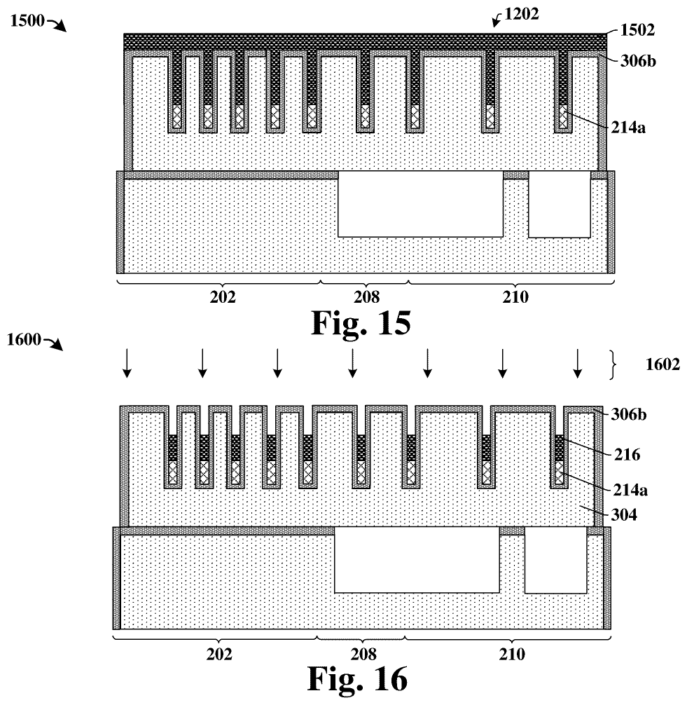

As shown in cross-sectional view 1600 of FIG. 16, the weighted core material layer (e.g., 1502 of FIG. 15) is recessed to form a weighted core material 216 that is to a non-zero distance below a top of the dielectric liner 306b. In some embodiments, the weighted core material 216 may also be recessed below a top of the second semiconductor body 304. In some embodiments, the weighted core material layer may be recessed by exposing the weighted core material layer to an etchant 1602 that has a high etching selectivity. The high etching selectivity will etch the weighted core material layer without significantly etching the dielectric liner 306b, so as to recess the weighted core material 216 below the dielectric liner 306b. In some embodiments, the etchant 1602 may comprise nitric acid, hydrochloric acid, and/or the like.

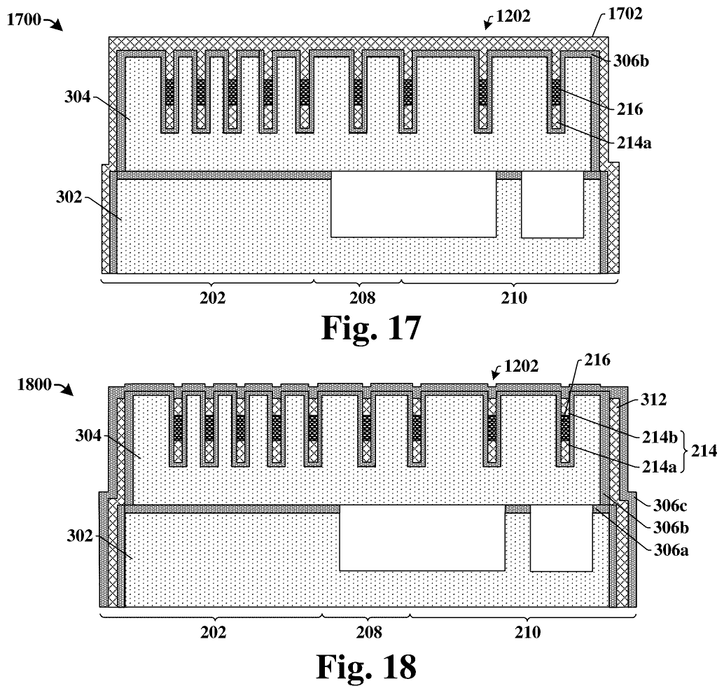

As shown in cross-sectional view 1700 of FIG. 17, an upper core material layer 1702 is formed onto a topmost surface of the weighted core material 216. In some embodiments, the upper core material layer 1702 may comprise a semiconductor material, such as polysilicon or the like. In some embodiments, the upper core material layer 1702 may be formed by way of a deposition process (e.g., a PVD process, a CVD process, a PE-CVD process, an ALD process, sputtering, or the like) onto the topmost surface of the weighted core material 216 and within the plurality of trenches 1202. In some embodiments, the upper core material layer 1702 may be formed to continuously extend from over the second semiconductor body 304 to along opposing outermost sidewalls of the first semiconductor body 302 and the second semiconductor body 304.

As shown in cross-sectional view 1800 of FIG. 18, the upper core material layer (e.g., 1702 of FIG. 17) is recessed to form an upper core material 214b that is confined within the plurality of trenches 1202 and to form a peripheral core material 312 along opposing sides of the first semiconductor body 302 and the second semiconductor body 304. In some embodiments, the upper core material 214b may be recessed below a topmost surface of the second semiconductor body 304. In some embodiments, the upper core material layer may be recessed by exposing the upper core material layer to an etchant (not shown) that has a high etching selectivity. The high etching selectivity will etch the upper core material layer without significantly etching the dielectric liner 306b, so as to recess the upper core material layer below the dielectric liner 306b.

After forming the upper core material 214b, a second dielectric layer 306c is formed over the dielectric liner 306b and the upper core material 214b. In some embodiments, the second dielectric layer 306c may be formed by way of a deposition process (e.g., a PVD process, a CVD process, a PE-CVD process, an ALD process, or the like).

As shown in cross-sectional view 1900 of FIG. 19, a part of the dielectric liner (e.g., 306b of FIG. 18) and a part of the second dielectric layer (e.g., 306c of FIG. 18) are removed from within the comb region 202 to form an opening 1902 that exposes the second semiconductor body 304. The opening 1902 is formed by sidewalls of a dielectric structure 306 and forms a plurality of comb fingers 104. The plurality of comb fingers 104 respectively comprise a dielectric cover 218 continuously extending around the core material 214 and the weighted core material 216. In some embodiments, the core material 214 covers topmost and bottommost surfaces of the weighted core material 216. In some embodiments, the dielectric liner (306b of FIG. 18) and the second dielectric layer (e.g., 306c of FIG. 18) may be selectively exposed to an etchant 1904 according to a mask 1906.

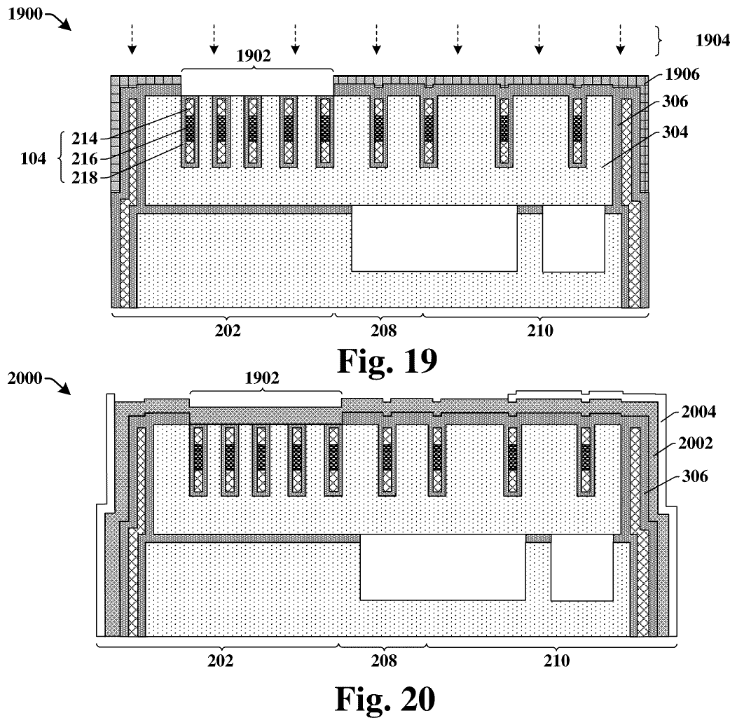

As shown in cross-sectional view 2000 of FIG. 20, a first semiconductor layer 2002 is formed within the opening 1902, over the dielectric structure 306, and along opposing outermost sidewalls of the dielectric structure 306. In some embodiments, the first semiconductor layer 2002 may comprise a semiconductor material, such as polysilicon. In some embodiments, the first semiconductor layer 2002 may be formed by way of a deposition process (e.g., a PVD process, a CVD process, a PE-CVD process, an ALD process, or the like).

After forming the first semiconductor layer 2002, an additional dielectric layer 2004 is formed over the first semiconductor layer 2002 and along opposing outermost sidewalls of the first semiconductor layer 2002. In some embodiments, the additional dielectric layer 2004 may be formed by way of a deposition process (e.g., a PVD process, a CVD process, a PE-CVD process, an ALD process, or the like). In some embodiments, the additional dielectric layer 2004 is formed to cover the first semiconductor layer 2002 and is subsequently patterned to remove a part of the additional dielectric layer 2004 from within the comb region 202 and the cantilever region 208. After patterning, the additional dielectric layer 2004 remains along sidewalls of the first semiconductor layer 2002 and over the first semiconductor layer 2002 within the frame region 210. In some embodiments, the additional dielectric layer 2004 may be removed from within the comb region 202 and the cantilever region 208 by selectively exposing the additional dielectric layer 2004 to an etchant (not shown) according to a mask formed over the additional dielectric layer 2004.

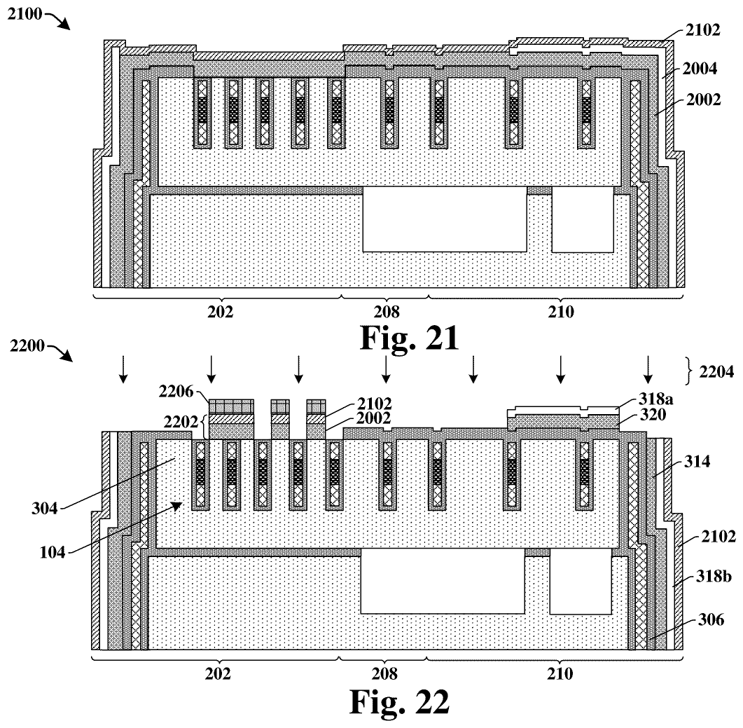

As shown in cross-sectional view 2100 of FIG. 21, a second semiconductor layer 2102 is formed over the first semiconductor layer 2002, over the additional dielectric layer 2004, and along opposing outermost sidewalls of the additional dielectric layer 2004. In some embodiments, the second semiconductor layer 2102 may comprise a semiconductor material, such as polysilicon. In some embodiments, the second semiconductor layer 2102 may be formed by way of a deposition process (e.g., a PVD process, a CVD process, a PE-CVD process, an ALD process, or the like).

As shown in cross-sectional view 2200 of FIG. 22, the first semiconductor layer 2002 and the second semiconductor layer 2102 are selectively patterned to form a plurality of sacrificial segments 2202 within the comb region 202. The plurality of sacrificial segments 2202 may comprise segments that are confined between neighboring ones of the plurality of comb fingers 104 and/or segments that straddle one or more of the plurality of comb fingers 104. Selective patterning of the first semiconductor layer 2002 also forms an upper semiconductor layer 320 over the second semiconductor body 304 and a peripheral first semiconductor layer 314 along opposing outermost sidewalls of the dielectric structure 306. In some embodiments, the additional dielectric layer 2004 may also be selectively patterned. Selective patterning of the additional dielectric layer 2004 forms a first additional dielectric 318a over the second semiconductor body 304 and a second additional dielectric 318b along opposing outermost sidewalls of the peripheral first semiconductor layer 314.

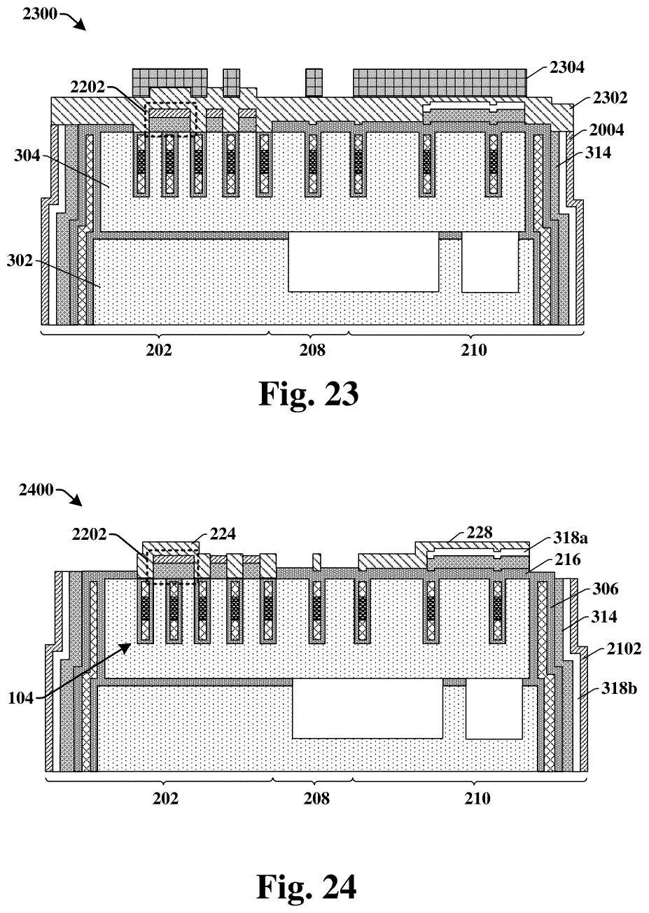

As shown in cross-sectional view 2300 of FIG. 23, a conductive layer 2302 is formed over the second semiconductor body 304. The conductive layer 2302 continuously extends over the comb region 202, the cantilever region 208, and the frame region 210. In some embodiments, the conductive layer 2302 may comprise a metal such as aluminum, tungsten, copper, and/or the like. In some embodiments, the conductive layer 2302 may be formed by way of a deposition process (e.g., a PVD process, a CVD process, a PE-CVD process, an ALD process, or the like) and/or an electroplating process.

As shown in cross-sectional view 2400 of FIG. 24, the conductive layer 2302 is patterned to form a conductive cap 224 within the comb region 202 and to further form one or more conductive connectors 228 within the frame region 210. The conductive cap 224 is vertically separated from one or more of the plurality of comb fingers 104 by the plurality of sacrificial segments 2202. The one or more conductive connectors 228 continuously extend from directly over the dielectric structure 306 to directly over the first additional dielectric 318a.

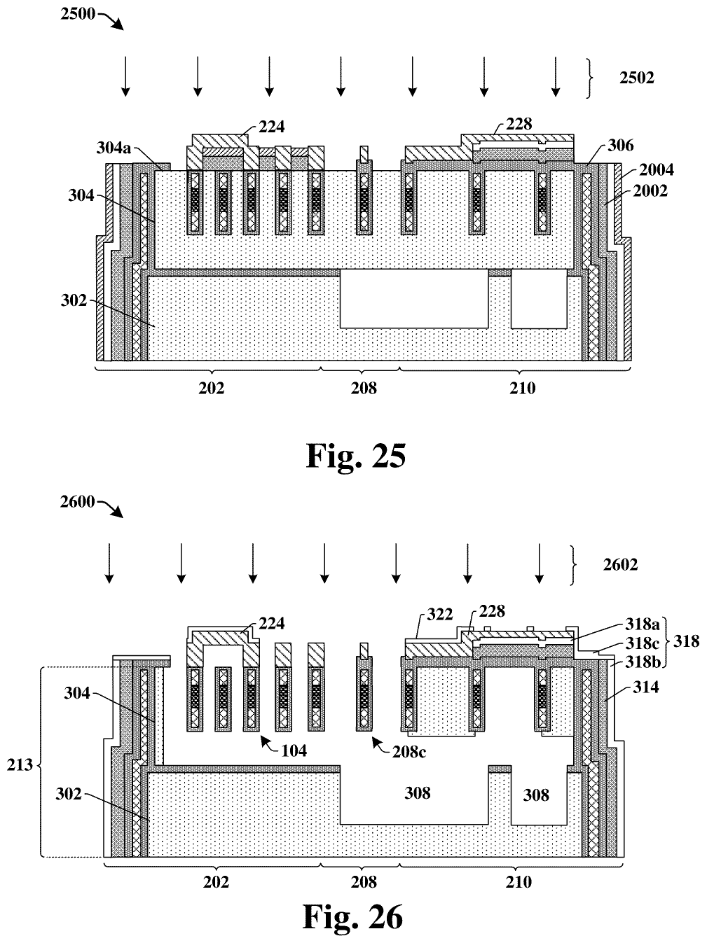

As shown in cross-sectional view 2500 of FIG. 25, the dielectric structure 306 is selectively patterned to expose parts of the second semiconductor body 304. In some embodiments, the dielectric structure 306 may be selectively patterned to expose the first side 304a of the second semiconductor body 304 within the comb region 202 and within the cantilever region 208.

As shown in cross-sectional view 2600 of FIG. 26, an additional dielectric material may be formed and then patterned to form a third additional dielectric 318c and an upper dielectric 322 over the conductive cap 224 and the one or more conductive connectors 228. The substrate 213 is subsequently etched to remove parts of the second semiconductor body 304 within of the comb region 202, the cantilever region 208, and the frame region 210. Removal of parts of the second semiconductor body 304 frees the plurality of comb fingers 104 and a cantilever 208c, so as to allow the plurality of comb fingers 104 and the cantilever 208c to move during operation of the MEMS structure. In some embodiments (not shown), after the second semiconductor body 304 is etched, the first semiconductor body 302 may be removed and the second semiconductor body 304 may be attached to a base substrate (e.g., as shown in FIG. 4C).

In some embodiments, the second semiconductor body 304 may be etched by exposing the second semiconductor body 304 to a wet etchant 2602. In some embodiments, the plurality of cavities 308 may influence an etching speed of the wet etchant 2602, so as to selectively remove the parts of the second semiconductor body 304 while leaving other parts of the second semiconductor body 304. In some embodiments, the wet etchant 2602 may comprise hydrofluoric acid (HF), potassium hydroxide (KOH), sodium hydroxide (NaOH), nitric acid (HNO₃), a wet etchant comprising chlorine, a wet etchant comprising fluorine, a wet etchant comprising chlorine and fluorine, and/or the like.

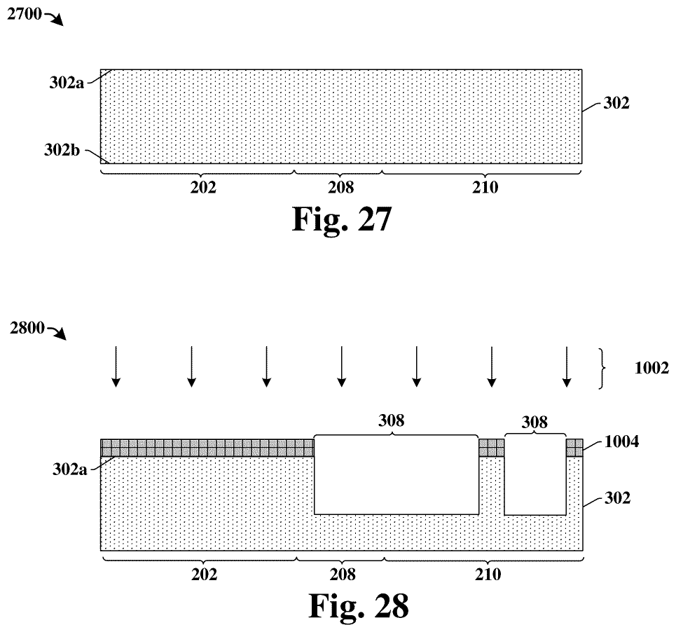

FIGS. 27-44 illustrate cross-sectional views of some embodiments of a method of forming a MEMS structure having a weighted comb-drive actuator. Although the cross-sectional views 2700-4400 shown in FIGS. 27-44 are described with reference to a method, it will be appreciated that the structures shown in FIGS. 27-44 are not limited to the method of formation but rather may stand alone separate of the method.

As shown in cross-sectional view 2700 of FIG. 27, a first semiconductor body 302 is provided. The first semiconductor body 302 has a first side 302a and a second side 302b, which opposes the first side 302a. The first semiconductor body 302 also comprises a comb region 202, a cantilever region 208, and a frame region 210.

As shown in cross-sectional view 2800 of FIG. 28, a plurality of cavities 308 are formed within the first side 302a of the first semiconductor body 302. The plurality of cavities 308 are formed by sidewalls and a recessed surface of the first semiconductor body 302.

As shown in cross-sectional view 2900 of FIG. 29, the first semiconductor body 302 is bonded to a second semiconductor body 304 to form a substrate 213. In some embodiments, a first dielectric layer 306a is formed along the first side 302a of the first semiconductor body 302. The first semiconductor body 302 is subsequently bonded to a second side 304b of the second semiconductor body 304 by way of the first dielectric layer 306a.

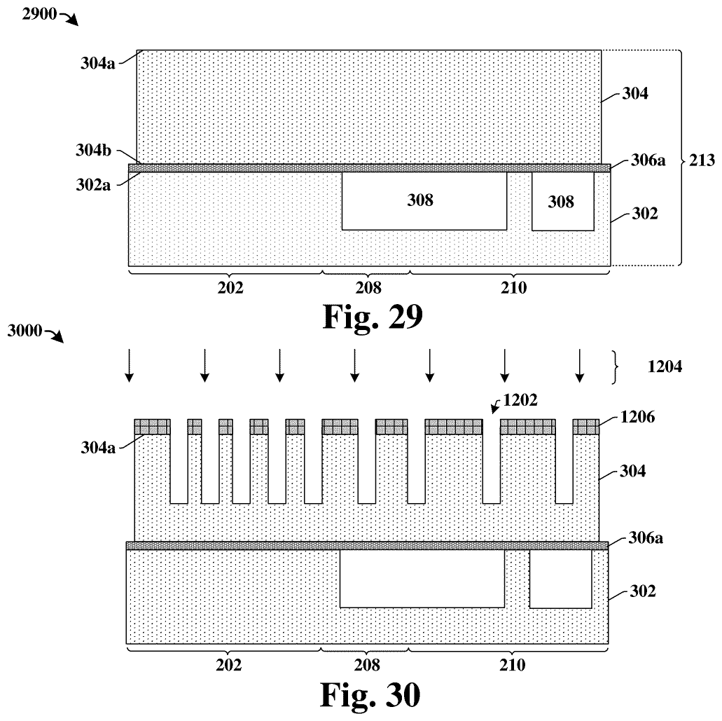

As shown in cross-sectional view 3000 of FIG. 30, a plurality of trenches 1202 are formed along the first side 304a of the second semiconductor body 304. The plurality of trenches 1202 are formed by sidewalls and a recessed surface of the second semiconductor body 304. In some embodiments, the plurality of trenches 1202 may be formed by selectively exposing the first side 304a of the second semiconductor body 304 to an etchant 1204 according to a mask 1206.

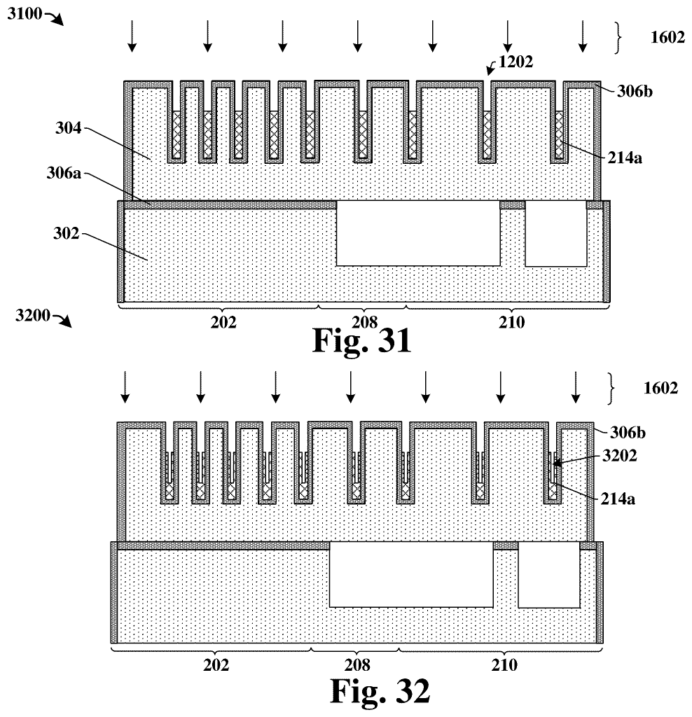

As shown in cross-sectional view 3100 of FIG. 31, a dielectric liner 306b is formed along interior surfaces of the second semiconductor body 304 that form the plurality of trenches 1202. In some embodiments, the dielectric liner 306b is formed to continuously extend from within the plurality of trenches 1202 to along opposing outermost sidewalls of the first semiconductor body 302, the first dielectric layer 306a, and the second semiconductor body 304.

A lower core material 214a is subsequently formed on the dielectric liner 306b and within the plurality of trenches 1202. In some embodiments, the lower core material 214a may be formed over a top of the dielectric liner 306b and subsequently recessed to to form the lower core material 214a to have a top that is a non-zero distance below a top of the dielectric liner 306b.

As shown in cross-sectional view 3200 of FIG. 32, the lower core material 214a is selectively patterned to form cavities 3202 within respective ones of the plurality of trenches 1202. The cavities 3202 are formed by sidewalls and a recessed surface of the lower core material 214a. In some embodiments, the cavities 3202 may be formed using a self aligned mask that extends along sidewalls of the dielectric liner 306b while exposing horizontally extending surfaces of the lower core material 214a.

As shown in cross-sectional view 3300 of FIG. 33, a weighted core material layer 1502 is formed onto a top of the lower core material 214a and within the cavities 3202 in the lower core material 214a. In some embodiments, the weighted core material layer 1502 may be formed to continuously extend from within the cavities 3202 in the lower core material 214a to over a top of the dielectric liner 306b.

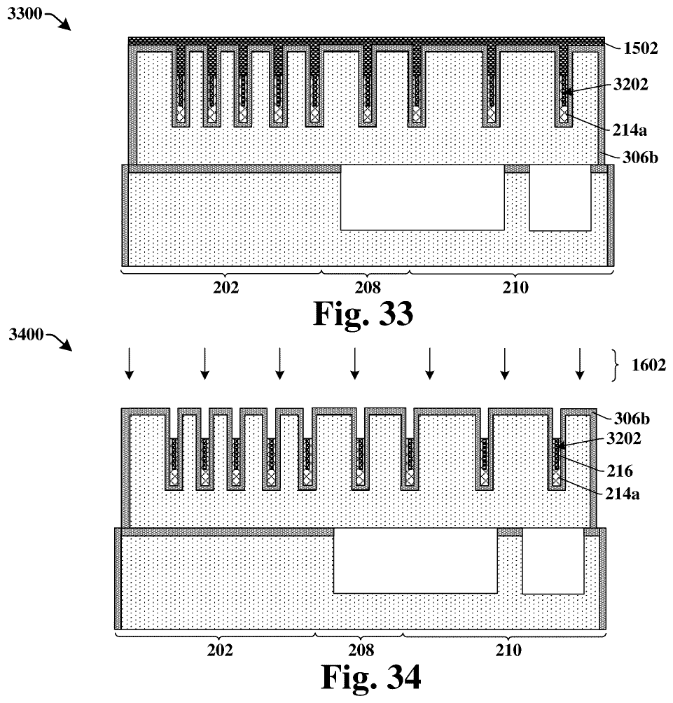

As shown in cross-sectional view 3400 of FIG. 34, the weighted core material layer (e.g., 1502 of FIG. 15) is recessed to form a weighted core material 216 that is confined within the cavities 3202 within the lower core material 214a. In some embodiments, the weighted core material layer may be recessed by exposing the weighted core material layer to an etchant 1602 that has a high etching selectivity.

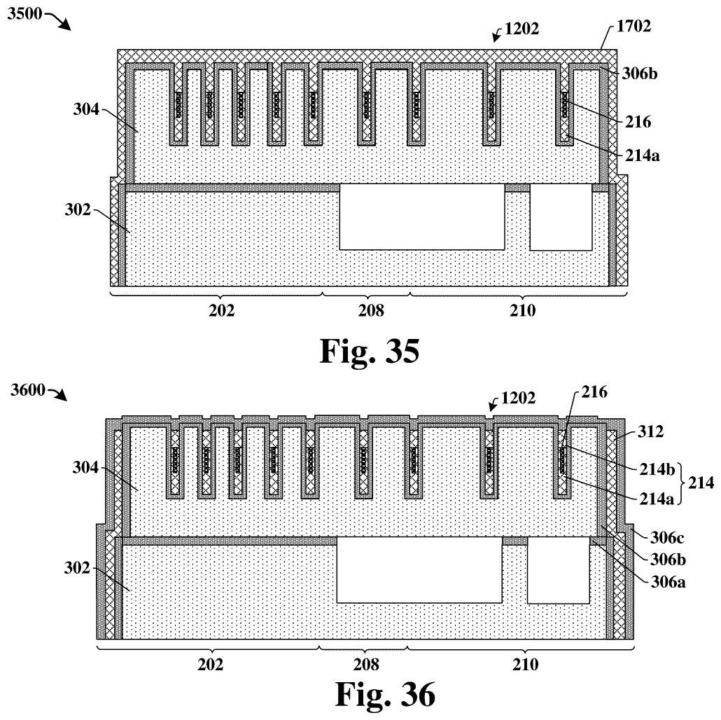

As shown in cross-sectional view 3500 of FIG. 35, an upper core material layer 1702 is formed onto topmost surfaces of both the lower core material 214a and the weighted core material 216. In some embodiments, the upper core material layer 1702 may comprise a semiconductor material, such as polysilicon or the like. In some embodiments, the upper core material layer 1702 may comprise a same material as the lower core material 214a. In other embodiments, the upper core material layer 1702 and the lower core material 214a may comprise different materials.

As shown in cross-sectional view 3600 of FIG. 36, the upper core material layer (e.g., 1702 of FIG. 17) is recessed to form an upper core material 214b that is confined within the plurality of trenches 1202 and to form a peripheral core material 312 along opposing sides of the first semiconductor body 302 and the second semiconductor body 304. In some embodiments, the upper core material 214b may be recessed below a topmost surface of the second semiconductor body 304. After forming the upper core material 214b, a second dielectric layer 306c is formed over the dielectric liner 306b and the upper core material 214b.

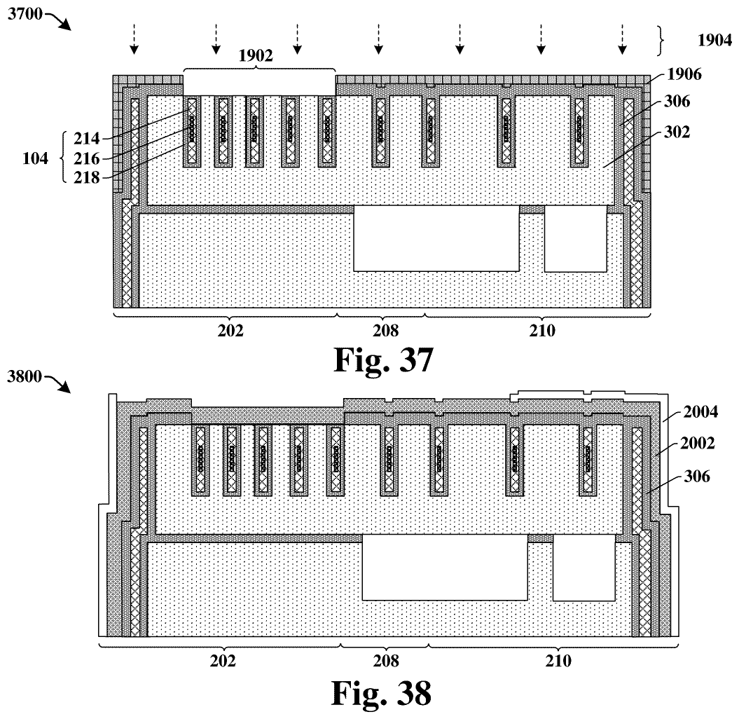

As shown in cross-sectional view 3700 of FIG. 37, a part of the dielectric liner (e.g., 306b of FIG. 36) and a part of the second dielectric layer (e.g., 306c of FIG. 36) are removed from within the comb region 202 to form an opening 1902 that exposes the second semiconductor body 304. The opening 1902 is formed by sidewalls of a dielectric structure 306 and forms a plurality of comb fingers 104. The plurality of comb fingers 104 respectively comprise a dielectric cover 218 continuously extending around the core material 214 and the weighted core material 216. In some embodiments, the dielectric liner (306b of FIG. 36) and the second dielectric layer (e.g., 306c of FIG. 36) may be selectively exposed to an etchant 1904 according to a mask 1906.

As shown in cross-sectional view 3800 of FIG. 38, a first semiconductor layer 2002 is formed within the opening 1902, over the dielectric structure 306, and along opposing outermost sidewalls of the dielectric structure 306.

After forming the first semiconductor layer 2002, an additional dielectric layer 2004 is formed over the first semiconductor layer 2002 and along opposing outermost sidewalls of the first semiconductor layer 2002. In some embodiments, the additional dielectric layer 2004 is formed to cover the first semiconductor layer 2002 and is subsequently patterned to remove the additional dielectric layer 2004 from within the comb region 202 and the cantilever region 208. After patterning, the additional dielectric layer 2004 remains along sidewalls of the first semiconductor layer 2002 and over the first semiconductor layer 2002 within the frame region 210. In some embodiments, the additional dielectric layer 2004 may be removed from within the comb region 202 and the cantilever region 208 by selectively exposing the additional dielectric layer 2004 to an etchant according to a mask formed over the additional dielectric layer 2004.

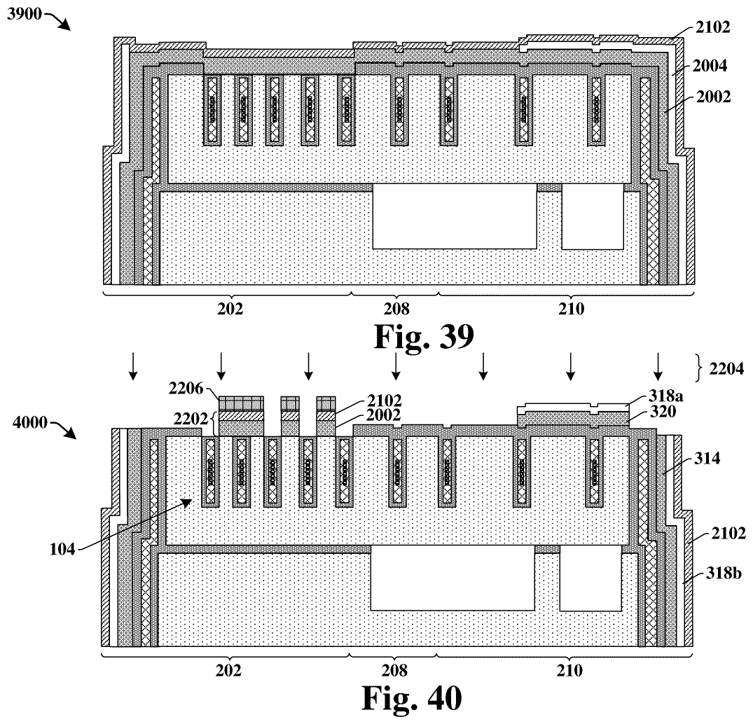

As shown in cross-sectional view 3900 of FIG. 39, a second semiconductor layer 2102 is formed over the first semiconductor layer 2002, over the additional dielectric layer 2004, and along opposing outermost sidewalls of the additional dielectric layer 2004.

As shown in cross-sectional view 4000 of FIG. 40, the first semiconductor layer 2002 and the second semiconductor layer 2102 are selectively patterned to form a plurality of sacrificial segments 2202 within the comb region 202. The plurality of sacrificial segments 2202 may comprise segments that are confined between neighboring ones of the plurality of comb fingers 104 and/or segments that straddle one or more of the plurality of comb fingers 104. Selective patterning of the first semiconductor layer 2002 also forms an upper semiconductor layer 320 over the second semiconductor body 304 and a peripheral first semiconductor layer 314 along opposing outermost sidewalls of the dielectric structure 306. In some embodiments, the additional dielectric layer 2004 may also be selectively patterned. Selective patterning of the additional dielectric layer 2004 forms a first additional dielectric 318a over the second semiconductor body 304 and a second additional dielectric 318b along opposing outermost sidewalls of the peripheral first semiconductor layer 314.

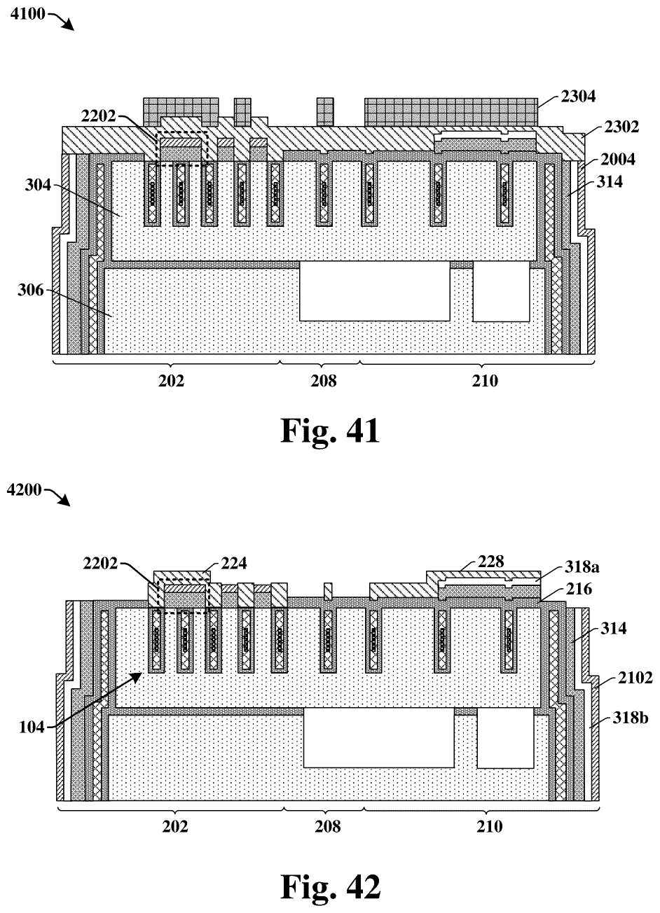

As shown in cross-sectional view 4100 of FIG. 41, a conductive layer 2302 is formed over the second semiconductor body 304. The conductive layer 2302 continuously extends over the comb region 202, the cantilever region 208, and the frame region 210.

As shown in cross-sectional view 4200 of FIG. 42, the conductive layer 2302 is patterned to form a conductive cap 224 within the comb region 202 and to further form one or more conductive connectors 228 within the frame region 210. The conductive cap 224 is vertically separated from one or more of the plurality of comb fingers 104 by the plurality of sacrificial segments 2202. The one or more conductive connectors 228 continuously extend from directly over the dielectric structure 306 to directly over the first additional dielectric 318a.

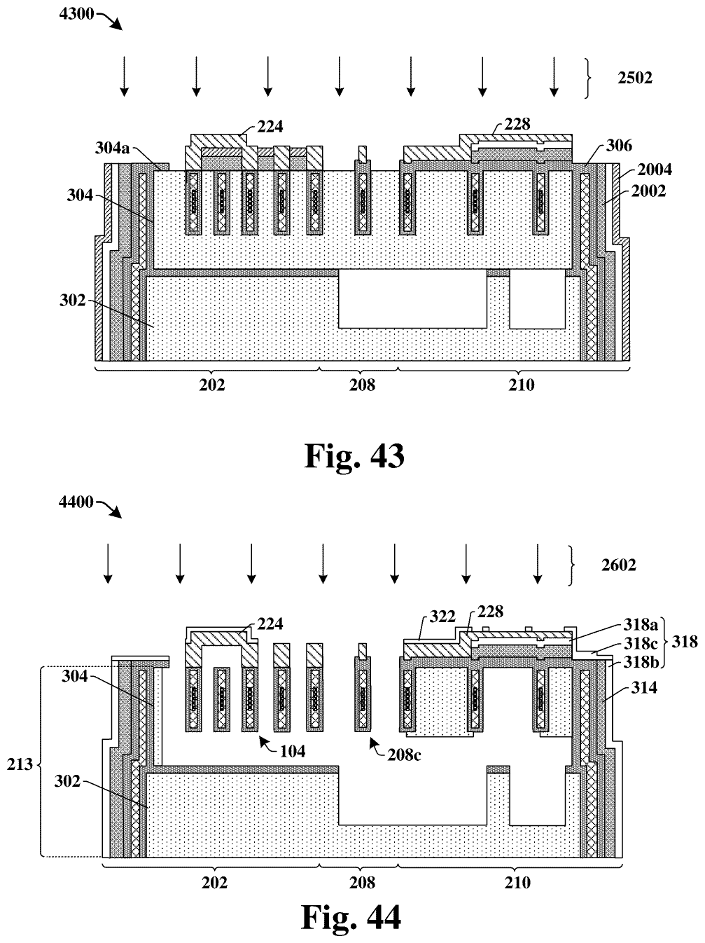

As shown in cross-sectional view 4300 of FIG. 43, the dielectric structure 306 is selectively patterned to expose parts of the second semiconductor body 304. In some embodiments, the dielectric structure 306 may be selectively patterned to expose the first side 304a of the second semiconductor body 304 within the comb region 202 and within the cantilever region 208.

As shown in cross-sectional view 4400 of FIG. 44, an additional dielectric material may be formed and then patterned to form a third additional dielectric 318c and an upper dielectric 322 over the conductive cap 224 and the one or more conductive connectors 228.

The substrate 213 is subsequently etched to remove parts of the second semiconductor body 304 within of the comb region 202, the cantilever region 208, and the frame region 210. Removal of parts of the second semiconductor body 304 frees the plurality of comb fingers 104 and a cantilever 208c, so as to allow the plurality of comb fingers 104 and the cantilever 208c to move during operation of the MEMS structure. In some embodiments (not shown), after the second semiconductor body 304 is etched, the first semiconductor body 302 may be removed and the second semiconductor body 304 may be attached to a base substrate (e.g., as shown in FIG. 4C).

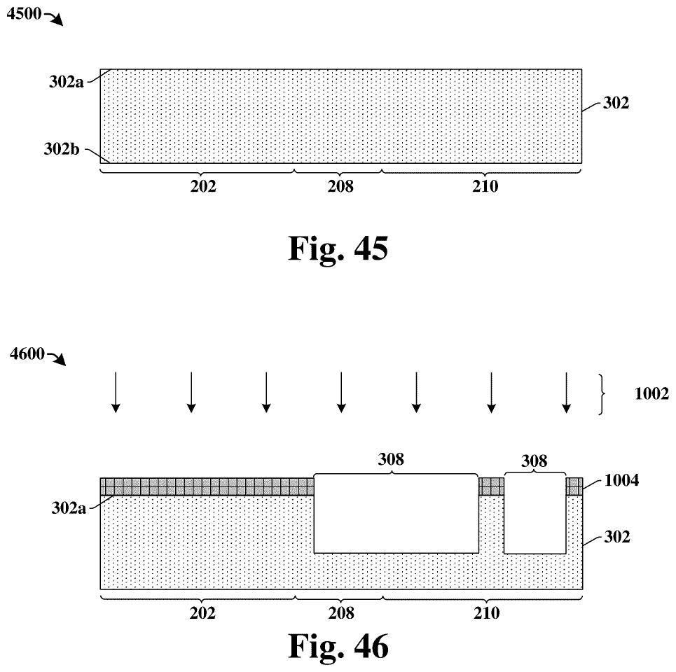

FIGS. 45-60 illustrate cross-sectional views of some embodiments of a method of forming a MEMS structure having a weighted comb-drive actuator. Although the cross-sectional views 4500-6000 shown in FIGS. 45-60 are described with reference to a method, it will be appreciated that the structures shown in FIGS. 45-60 are not limited to the method of formation but rather may stand alone separate of the method.

As shown in cross-sectional view 4500 of FIG. 45, a first semiconductor body 302 is provided. The first semiconductor body 302 has a first side 302a and a second side 302b, which opposes the first side 302a. The first semiconductor body 302 also comprises a comb region 202, a cantilever region 208, and a frame region 210.

As shown in cross-sectional view 4600 of FIG. 46, a plurality of cavities 308 are formed within the first side 302a of the first semiconductor body 302. The plurality of cavities 308 are formed by sidewalls and a recessed surface of the first semiconductor body 302.

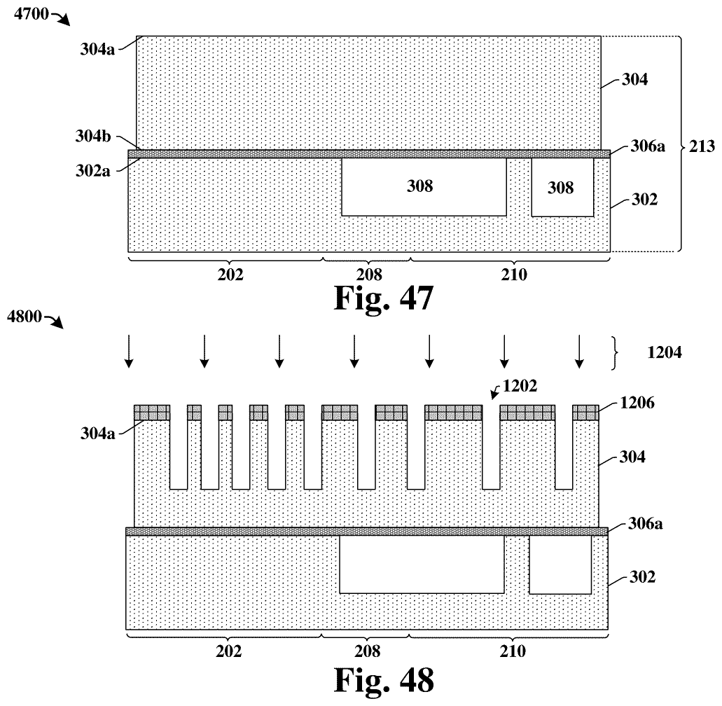

As shown in cross-sectional view 4700 of FIG. 47, the first semiconductor body 302 is bonded to a second semiconductor body 304 to form a substrate 213. In some embodiments, a first dielectric layer 306a is formed along the first side 302a of the first semiconductor body 302. The first semiconductor body 302 is subsequently bonded to a second side 304b of the second semiconductor body 304 by way of the first dielectric layer 306a.

As shown in cross-sectional view 4800 of FIG. 48, a plurality of trenches 1202 are formed along a first side 304a of the second semiconductor body 304. The plurality of trenches 1202 are formed by sidewalls and a recessed surface of the second semiconductor body 304. In some embodiments, the plurality of trenches 1202 may be formed by selectively exposing the first side 304a of the second semiconductor body 304 to an etchant 1204 according to a mask 1206.

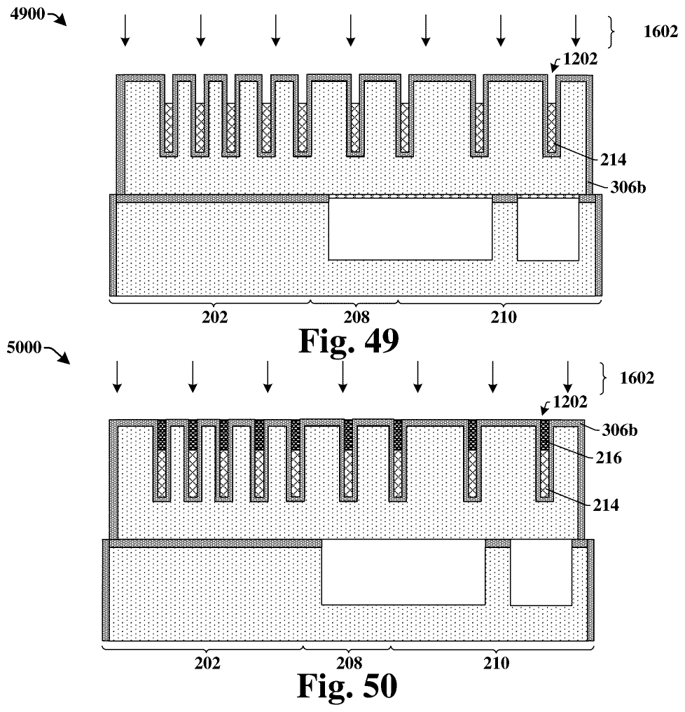

As shown in cross-sectional view 4900 of FIG. 49, a dielectric liner 306b is formed along interior surfaces of the second semiconductor body 304 forming the plurality of trenches 1202. In some embodiments, the dielectric liner 306b is formed to continuously extend from within the plurality of trenches 1202 to along opposing outermost sidewalls of the first semiconductor body 302, the first dielectric layer 306a, and the second semiconductor body 304. A lower core material layer is subsequently formed on the dielectric liner 306b. The lower core material layer may be formed over a top of the dielectric liner 306b and subsequently recessed to to form a core material 214 that is a non-zero distance below a top of the dielectric liner 306b.

As shown in cross-sectional view 5000 of FIG. 50, a weighted core material layer is formed onto a top of the core material 214 and within the plurality of trenches 1202. In some embodiments, the weighted core material layer may be formed to continuously extend from within the plurality of trenches 1202 to over a top of the dielectric liner 306b. The weighted core material layer is subsequently recessed to form a weighted core material 216 that is confined within the plurality of trenches 1202.

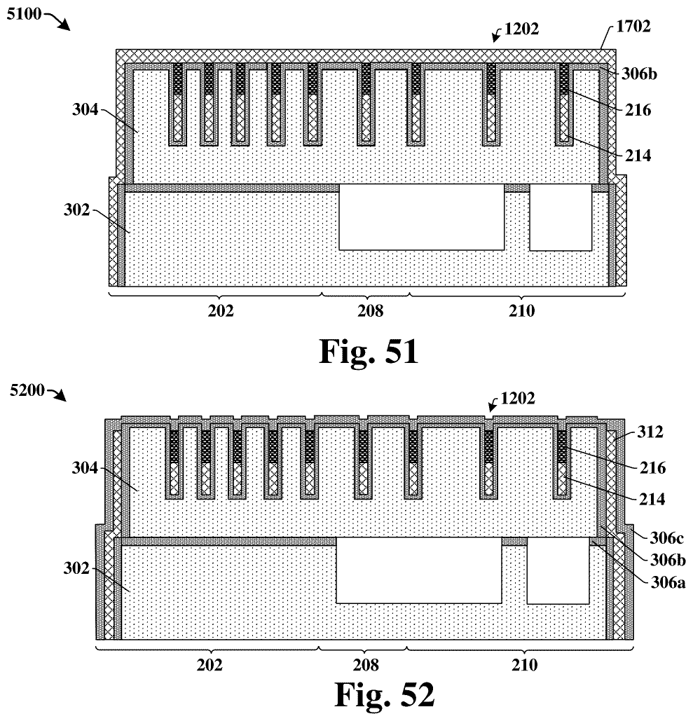

As shown in cross-sectional view 5100 of FIG. 51, an upper core material layer 1702 is formed onto topmost surfaces the weighted core material 216. In some embodiments, the upper core material layer 1702 continuously extends from over the topmost surfaces of the weighted core material 216 to along opposing outermost sidewalls of the dielectric liner 306b.

As shown in cross-sectional view 5200 of FIG. 52, parts of the upper core material layer (e.g., 1702 of FIG. 51) are removed from directly over the second semiconductor body 304 leaving a peripheral core material 312 along opposing sides of the first semiconductor body 302 and the second semiconductor body 304. After removing the parts of the upper core material layer, a second dielectric layer 306c is formed over the dielectric liner 306b and the weighted core material 216.

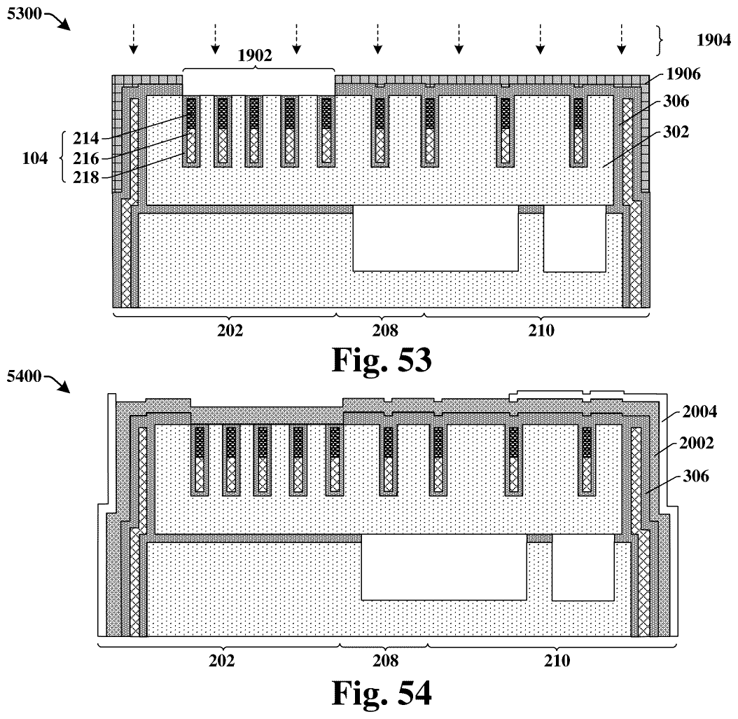

As shown in cross-sectional view 5300 of FIG. 53, a part of the dielectric liner (e.g., 306b of FIG. 52) and a part of the second dielectric layer (e.g., 306c of FIG. 52) are removed from within the comb region 202 to form an opening 1902 that exposes the second semiconductor body 304. The opening 1902 is formed by sidewalls of a dielectric structure 306 and forms a plurality of comb fingers 104. The plurality of comb fingers 104 respectively comprise a dielectric cover 218 continuously extending around the core material 214 and the weighted core material 216. In some embodiments, the dielectric liner (306b of FIG. 52) and the second dielectric layer (e.g., 306c of FIG. 52) may be selectively exposed to an etchant 1904 according to a mask 1906.

As shown in cross-sectional view 5400 of FIG. 54, a first semiconductor layer 2002 is formed within the opening 1902, over the dielectric structure 306, and along opposing outermost sidewalls of the dielectric structure 306. After forming the first semiconductor layer 2002, an additional dielectric layer 2004 is formed over the first semiconductor layer 2002 and along opposing outermost sidewalls of the first semiconductor layer 2002. In some embodiments, the additional dielectric layer 2004 is formed to cover the first semiconductor layer 2002 and is subsequently patterned to remove the additional dielectric layer 2004 from within the comb region 202 and the cantilever region 208. After patterning, the additional dielectric layer 2004 remains along sidewalls of the first semiconductor layer 2002 and over the first semiconductor layer 2002 within the frame region 210.

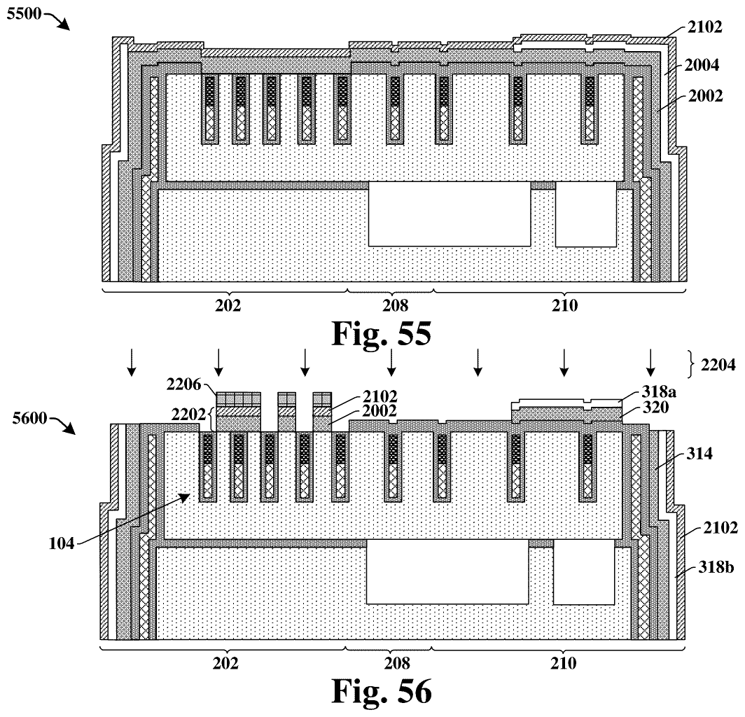

As shown in cross-sectional view 5500 of FIG. 55, a second semiconductor layer 2102 is formed over the first semiconductor layer 2002, over the additional dielectric layer 2004, and along opposing outermost sidewalls of the additional dielectric layer 2004.

As shown in cross-sectional view 5600 of FIG. 56, the first semiconductor layer 2002 and the second semiconductor layer 2102 are selectively patterned to form a plurality of sacrificial segments 2202 within the comb region 202. The plurality of sacrificial segments 2202 may comprise segments that are confined between neighboring ones of the plurality of comb fingers 104 and/or segments that straddle one or more of the plurality of comb fingers 104. Selective patterning of the first semiconductor layer 2002 also forms an upper semiconductor layer 320 over the second semiconductor body 304 and a peripheral first semiconductor layer 314 along opposing outermost sidewalls of the dielectric structure 306. In some embodiments, the additional dielectric layer 2004 may also be selectively patterned. Selective patterning of the additional dielectric layer 2004 forms a first additional dielectric 318a over the second semiconductor body 304 and a second additional dielectric 318b along opposing outermost sidewalls of the peripheral first semiconductor layer 314.

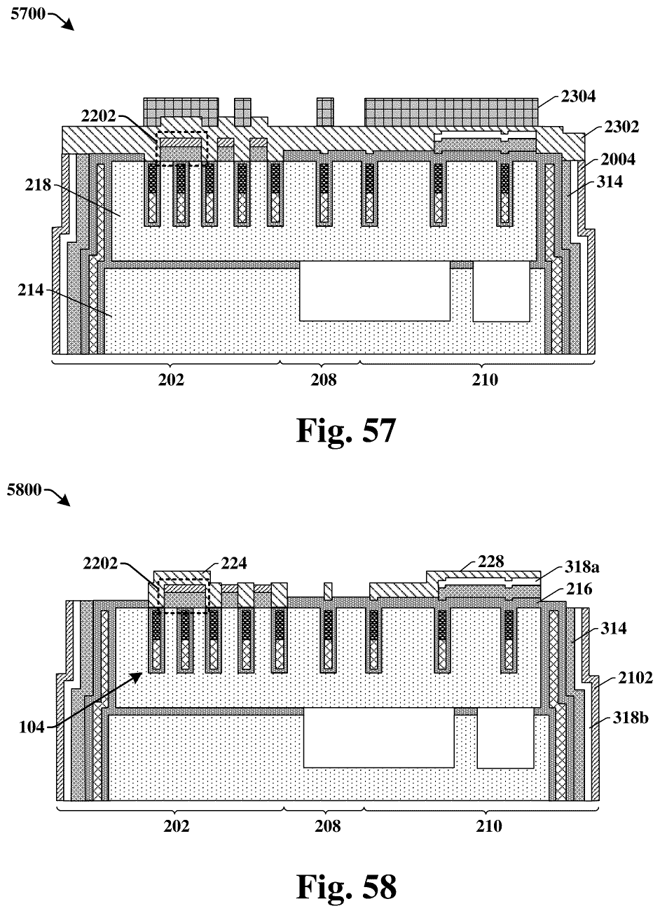

As shown in cross-sectional view 5700 of FIG. 57, a conductive layer 2302 is formed over the second semiconductor body 304. The conductive layer 2302 continuously extends over the comb region 202, the cantilever region 208, and the frame region 210.

As shown in cross-sectional view 5800 of FIG. 58, the conductive layer 2302 is patterned to form a conductive cap 224 within the comb region 202 and to further form one or more conductive connectors 228 within the frame region 210. The conductive cap 224 is vertically separated from one or more of the plurality of comb fingers 104 by the plurality of sacrificial segments 2202. The one or more conductive connectors 228 continuously extend from directly over the dielectric structure 306 to directly over the first additional dielectric 318a.

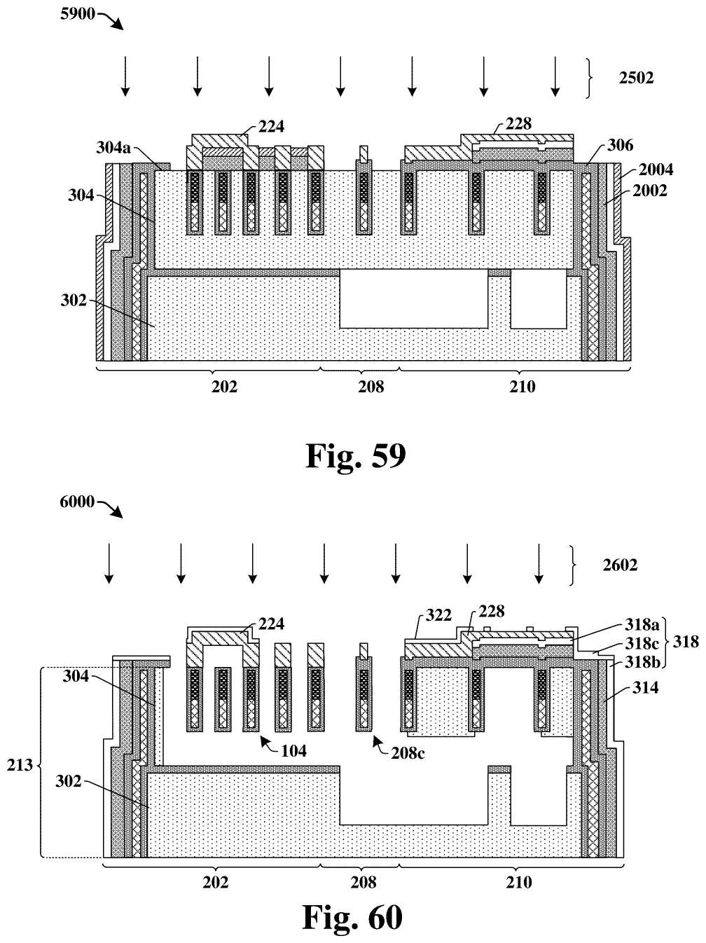

As shown in cross-sectional view 5900 of FIG. 59, the dielectric structure 306 is selectively patterned to expose parts of the second semiconductor body 304. In some embodiments, the dielectric structure 306 may be selectively patterned to expose the first side 304a of the second semiconductor body 304 within the comb region 202 and within the cantilever region 208.

As shown in cross-sectional view 6000 of FIG. 60, an additional dielectric material may be formed and then patterned to form a third additional dielectric 318c and an upper dielectric 322 over the conductive cap 224 and the one or more conductive connectors 228.

The substrate 213 is subsequently etched to remove parts of the second semiconductor body 304 within of the comb region 202, the cantilever region 208, and the frame region 210. In some embodiments (not shown), after the second semiconductor body 304 is etched, the first semiconductor body 302 may be removed and the second semiconductor body 304 may be attached to a base substrate (e.g., as shown in FIG. 4C).

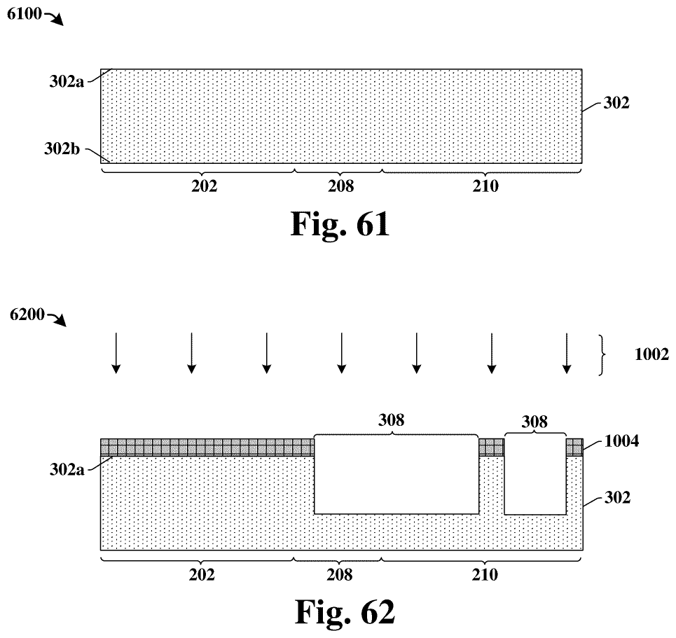

FIGS. 61-76 illustrate cross-sectional views of some embodiments of a method of forming a MEMS structure having a weighted comb-drive actuator.

As shown in cross-sectional view 6100 of FIG. 61, a first semiconductor body 302 is provided. The first semiconductor body 302 has a first side 302a and a second side 302b, which opposes the first side 302a. The first semiconductor body 302 also comprises a comb region 202, a cantilever region 208, and a frame region 210.

As shown in cross-sectional view 6200 of FIG. 62, a plurality of cavities 308 are formed within the first side 302a of the first semiconductor body 302. The plurality of cavities 308 are formed by sidewalls and a recessed surface of the first semiconductor body 302.

As shown in cross-sectional view 6300 of FIG. 63, the first semiconductor body 302 is bonded to a second semiconductor body 304 to form a substrate 213. In some embodiments, a first dielectric layer 306a is formed along the first side 302a of the first semiconductor body 302. The first semiconductor body 302 is subsequently bonded to a second side 304b of the second semiconductor body 304 by way of the first dielectric layer 306a.

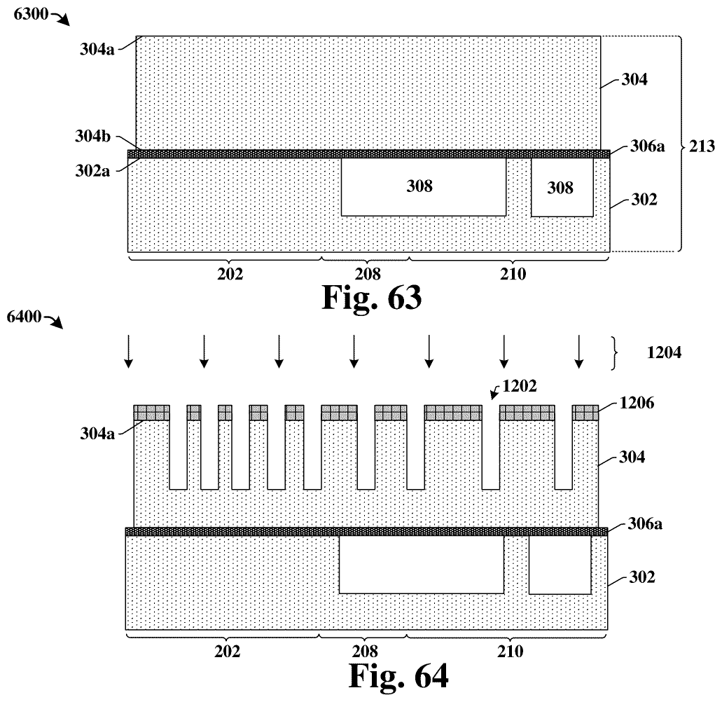

As shown in cross-sectional view 6400 of FIG. 64, a plurality of trenches 1202 are formed along a first side 304a of the second semiconductor body 304. The plurality of trenches 1202 are formed by sidewalls and a recessed surface of the second semiconductor body 304. In some embodiments, the plurality of trenches 1202 may be formed by selectively exposing the first side 304a of the second semiconductor body 304 to an etchant 1204 according to a mask 1206.

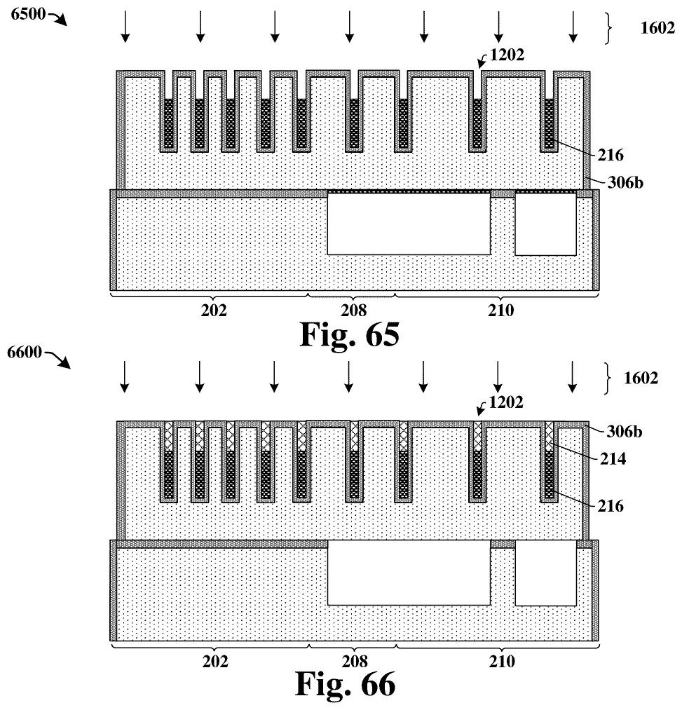

As shown in cross-sectional view 6500 of FIG. 65, a dielectric liner 306b is formed along interior surfaces of second semiconductor body 304 forming the plurality of trenches 1202. In some embodiments, the dielectric liner 306b is formed to continuously extend from within the plurality of trenches 1202 to along opposing outermost sidewalls of the first semiconductor body 302, the first dielectric layer 306a, and the second semiconductor body 304. A weighted core material layer is subsequently formed on the dielectric liner 306b. The weighted core material layer may be formed over a top of the dielectric liner 306b and subsequently recessed to to form a weighted core material 216 that is a non-zero distance below a top of the dielectric liner 306b.

As shown in cross-sectional view 6600 of FIG. 66, a lower core material layer is formed onto a top of the weighted core material 216 and within the plurality of trenches 1202. In some embodiments, the weighted core material layer may be formed to continuously extend from within the plurality of trenches 1202 to over a top of the dielectric liner 306b. The lower core material layer is recessed to form a core material 214 that is confined within the plurality of trenches 1202.

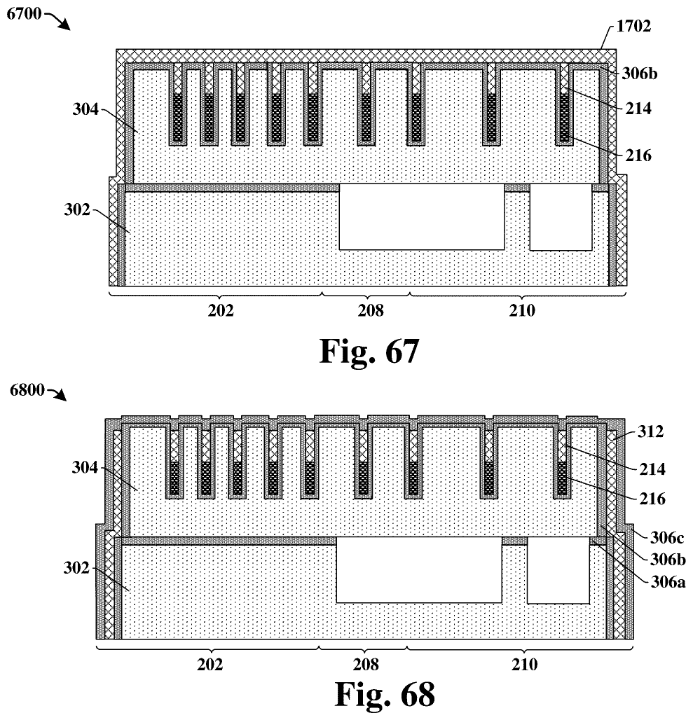

As shown in cross-sectional view 6700 of FIG. 67, an upper core material layer 1702 is formed onto topmost surfaces the core material 214. In some embodiments, the upper core material layer 1702 continuously extends from over the topmost surfaces of the core material 214 to along opposing outermost sidewalls of the dielectric liner 306b.

As shown in cross-sectional view 6800 of FIG. 68, parts of the upper core material layer (e.g., 1702 of FIG. 67) are removed from directly over the second semiconductor body 304 leaving a peripheral core material 312 along opposing sides of the first semiconductor body 302 and the second semiconductor body 304. After removing the parts of the upper core material layer, a second dielectric layer 306c is formed over the dielectric liner 306b and the core material 214.

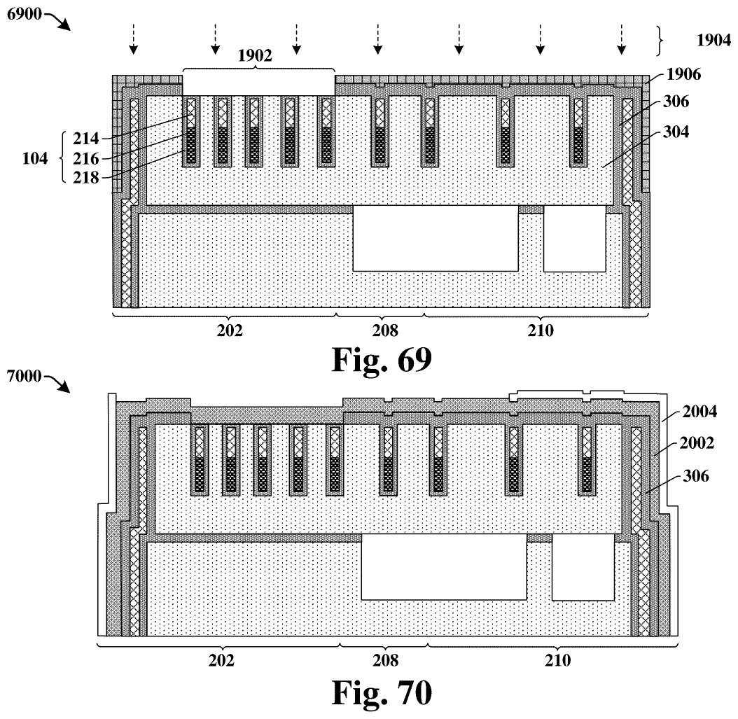

As shown in cross-sectional view 6900 of FIG. 69, a part of the dielectric liner (e.g., 306b of FIG. 68) and a part of the second dielectric layer (e.g., 306c of FIG. 68) are removed from within the comb region 202 to form an opening 1902 that exposes the second semiconductor body 304. The opening 1902 is formed by sidewalls of a dielectric structure 306 and forms a plurality of comb fingers 104. The plurality of comb fingers 104 respectively comprise a dielectric cover 218 continuously extending around the core material 214 and the weighted core material 216.

As shown in cross-sectional view 7000 of FIG. 70, a first semiconductor layer 2002 is formed within the opening 1902, over the dielectric structure 306, and along opposing outermost sidewalls of the dielectric structure 306. After forming the first semiconductor layer 2002, an additional dielectric layer 2004 is formed over the first semiconductor layer 2002 and along opposing outermost sidewalls of the first semiconductor layer 2002. In some embodiments, the additional dielectric layer 2004 is formed to cover the first semiconductor layer 2002 and is subsequently patterned to remove the additional dielectric layer 2004 from within the comb region 202 and the cantilever region 208. After patterning, the additional dielectric layer 2004 remains along sidewalls of the first semiconductor layer 2002 and over the first semiconductor layer 2002 within the frame region 210.

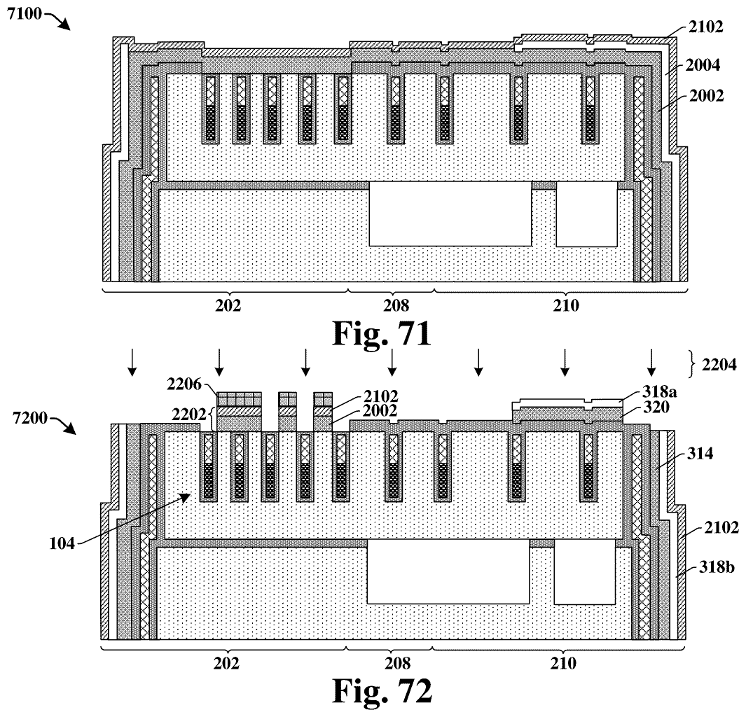

As shown in cross-sectional view 7100 of FIG. 71, a second semiconductor layer 2102 is formed over the first semiconductor layer 2002, over the additional dielectric layer 2004, and along opposing outermost sidewalls of the additional dielectric layer 2004.

As shown in cross-sectional view 7200 of FIG. 72, the first semiconductor layer 2002 and the second semiconductor layer 2102 are selectively patterned to form a plurality of sacrificial segments 2202 within the comb region 202. The plurality of sacrificial segments 2202 may comprise segments that are confined between neighboring ones of the plurality of comb fingers 104 and/or segments that straddle one or more of the plurality of comb fingers 104. Selective patterning of the first semiconductor layer 2002 also forms an upper semiconductor layer 320 over the second semiconductor body 304 and a peripheral first semiconductor layer 314 along opposing outermost sidewalls of the dielectric structure 306. In some embodiments, the additional dielectric layer 2004 may also be selectively patterned. Selective patterning of the additional dielectric layer 2004 forms a first additional dielectric 318a over the second semiconductor body 304 and a second additional dielectric 318b along opposing outermost sidewalls of the peripheral first semiconductor layer 314.

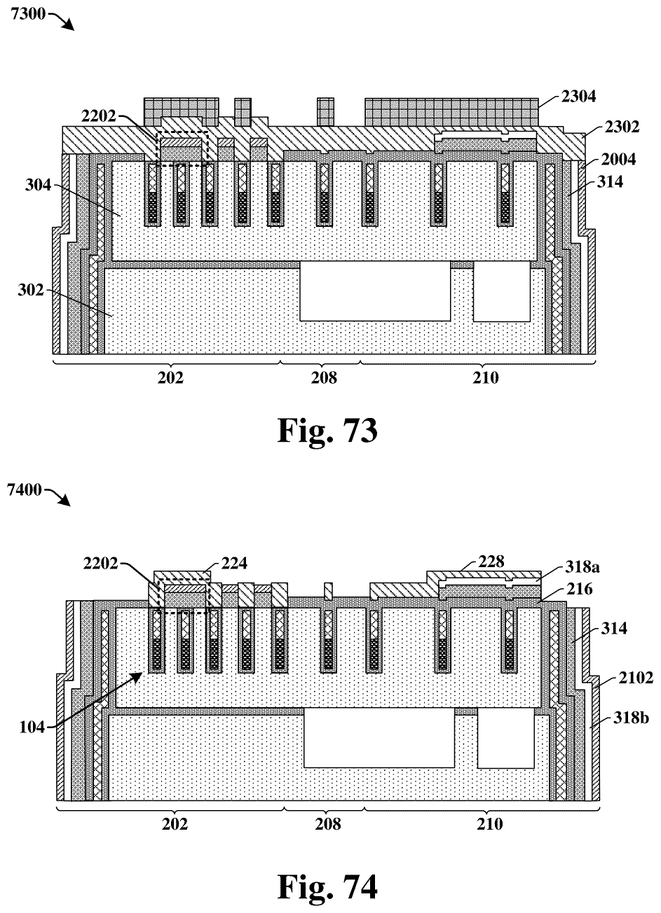

As shown in cross-sectional view 7300 of FIG. 73, a conductive layer 2302 is formed over the second semiconductor body 304. The conductive layer 2302 continuously extends over the comb region 202, the cantilever region 208, and the frame region 210.

As shown in cross-sectional view 7400 of FIG. 74, the conductive layer 2302 is patterned to form a conductive cap 224 within the comb region 202 and to further form one or more conductive connectors 228 within the frame region 210. The conductive cap 224 is vertically separated from one or more of the plurality of comb fingers 104 by the plurality of sacrificial segments 2202. The one or more conductive connectors 228 continuously extends from directly over the dielectric structure 306 to directly over the first additional dielectric 318a.

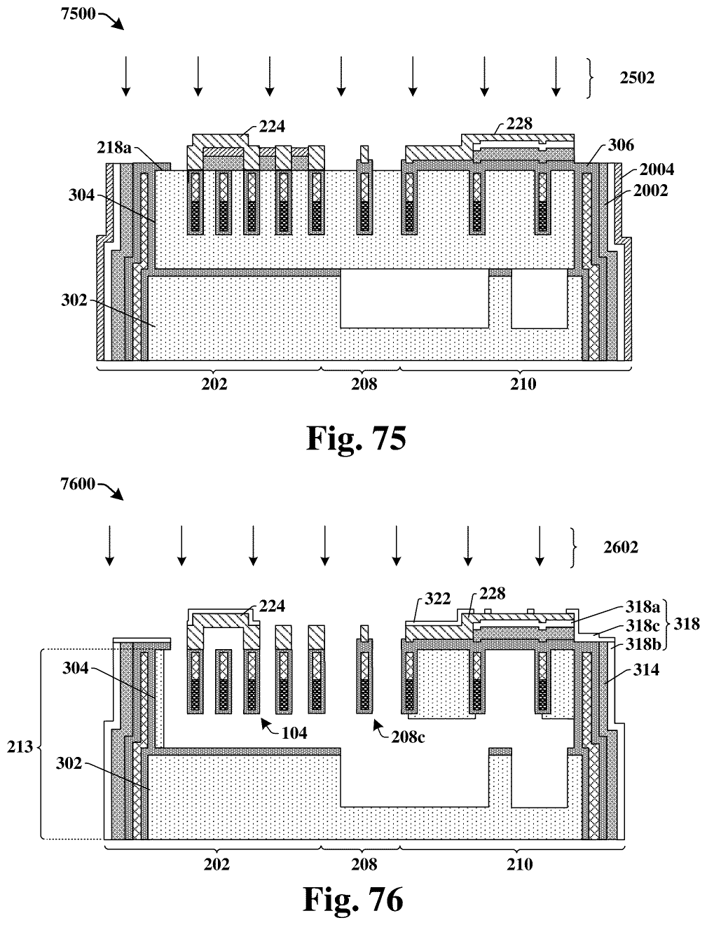

As shown in cross-sectional view 7500 of FIG. 75, the dielectric structure 306 is selectively patterned to expose parts of the second semiconductor body 304. In some embodiments, the dielectric structure 306 may be selectively patterned to expose the first side 304a of the second semiconductor body 304 within the comb region 202 and within the cantilever region 208.

As shown in cross-sectional view 7600 of FIG. 76, an additional dielectric material may be formed and then patterned to form a third additional dielectric 318c and an upper dielectric 322 over the conductive cap 224 and the one or more conductive connectors 228.

The substrate 213 is subsequently etched to remove parts of the second semiconductor body 304 within of the comb region 202, the cantilever region 208, and the frame region 210. In some embodiments (not shown), after the second semiconductor body 304 is etched, the first semiconductor body 302 may be removed and the second semiconductor body 304 may be attached to a base substrate (e.g., as shown in FIG. 4C).

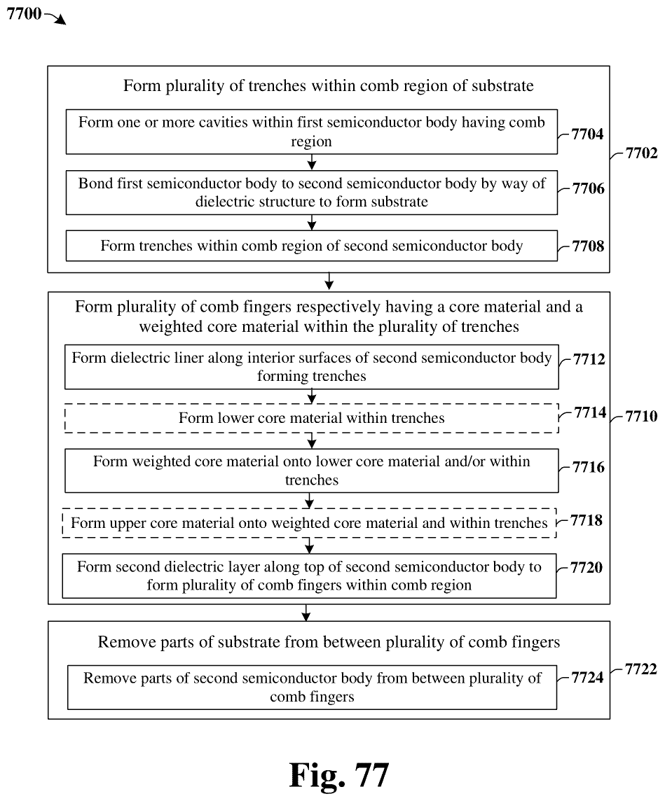

FIG. 77 illustrates a flow diagram of some embodiments of a method 7700 of forming an image sensor IC comprising a disclosed etch block structure.

While method 7700 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 7702, a plurality of trenches are formed within a comb region of a substrate. In some embodiments, act 7702 may be performed according to acts 7704-7708.

At act 7704, one or more cavities are formed within a first semiconductor body. FIG. 10 illustrates a cross-sectional view 1000 of some embodiments corresponding to act 7704. FIG. 28 illustrates a cross-sectional view 2800 of some additional embodiments corresponding to act 7704. FIG. 46 illustrates a cross-sectional view 4600 of some additional embodiments corresponding to act 7704. FIG. 62 illustrates a cross-sectional view 6200 of some additional embodiments corresponding to act 7704.

At act 7706, the first semiconductor body is bonded to a second semiconductor body by way of a dielectric layer to form a substrate. FIG. 11 illustrates a cross-sectional view 1100 of some embodiments corresponding to act 7706. FIG. 29 illustrates a cross-sectional view 2900 of some additional embodiments corresponding to act 7706. FIG. 47 illustrates a cross-sectional view 4700 of some additional embodiments corresponding to act 7706. FIG. 63 illustrates a cross-sectional view 6300 of some additional embodiments corresponding to act 7706.

At act 7708, a plurality of trenches are formed within the second semiconductor body. FIG. 12 illustrates a cross-sectional view 1200 of some embodiments corresponding to act 7708. FIG. 30 illustrates a cross-sectional view 3000 of some additional embodiments corresponding to act 7708. FIG. 48 illustrates a cross-sectional view 4800 of some additional embodiments corresponding to act 7708. FIG. 64 illustrates a cross-sectional view 6400 of some additional embodiments corresponding to act 7708.

At act 7710, a plurality of comb fingers, respectively having a weighted core material, are formed within the plurality of trenches. In some embodiments, act 7710 may be performed according to acts 7712-7720.

At act 7712, a dielectric liner is formed along interior surfaces of the second semiconductor body forming the plurality of trenches. FIG. 13 illustrates a cross-sectional view 1300 of some embodiments corresponding to act 7712. FIG. 31 illustrates a cross-sectional view 3100 of some additional embodiments corresponding to act 7712. FIG. 49 illustrates a cross-sectional view 4900 of some additional embodiments corresponding to act 7712. FIG. 65 illustrates a cross-sectional view 6500 of some additional embodiments corresponding to act 7712.

At act 7714, a lower core material may be formed within the plurality of trenches. FIGS. 13-14 illustrate cross-sectional views, 1300 and 1400, of some embodiments corresponding to act 7714. FIGS. 31-32 illustrate cross-sectional views, 3100 and 3200, of some additional embodiments corresponding to act 7714. FIG. 49 illustrates a cross-sectional view 4900 of some additional embodiments corresponding to act 7714.

At act 7716, a weighted core material is formed onto the lower core material and/or within the plurality of trenches. FIGS. 15-16 illustrate cross-sectional views, 1500 and 1600, of some embodiments corresponding to act 7716. FIGS. 33-34 illustrate cross-sectional views, 3300 and 3400, of some additional embodiments corresponding to act 7716. FIG. 50 illustrates a cross-sectional view 5000 of some additional embodiments corresponding to act 7716. FIG. 65 illustrates a cross-sectional view 6500 of some additional embodiments corresponding to act 7716.

At act 7718, an upper core material may be formed onto the weighted core material and within the plurality of trenches. FIGS. 17-18 illustrate cross-sectional views, 1700 and 1800, of some embodiments corresponding to act 7718. FIGS. 35-36 illustrate cross-sectional views, 3500 and 3600, of some additional embodiments corresponding to act 7718. FIG. 66 illustrates a cross-sectional view 6600 of some additional embodiments corresponding to act 7718.

At act 7720, a second dielectric layer along top of second semiconductor body to form a plurality of comb fingers within the comb region. FIGS. 18-19 illustrate cross-sectional views, 1800 and 1900, of some embodiments corresponding to act 7720. FIGS. 36-37 illustrate cross-sectional views, 3600 and 3700, of some additional embodiments corresponding to act 7720. FIGS. 52-53 illustrate cross-sectional views, 5200 and 5300, of some additional embodiments corresponding to act 7720. FIGS. 68-69 illustrate cross-sectional views, 6800 and 6900, of some additional embodiments corresponding to act 7720.

At act 7722, parts of the substrate are removed from between plurality of comb fingers. In some embodiments, act 7722 may be performed according to act 7724.

At act 7724, parts of the second semiconductor body are removed from between plurality of comb fingers. FIG. 26 illustrates a cross-sectional view 2600 of some embodiments corresponding to act 7724. FIG. 44 illustrates a cross-sectional view 4400 of some additional embodiments corresponding to act 7724. FIG. 60 illustrates a cross-sectional view 4800 of some additional embodiments corresponding to act 7724. FIG. 76 illustrates a cross-sectional view 6400 of some additional embodiments corresponding to act 7724.

Accordingly, in some embodiments, the present disclosure relates to a MEMS structure comprising a weighted comb-drive actuator comprising a plurality of fingers that include a core material and a weighted core material.

In some embodiments, the present disclosure relates to a MEMS (Microelectromechanical systems) structure. The MEMS structure includes a first comb structure having a first plurality of comb fingers extending outward from a first branch; a second comb structure having a second plurality of comb fingers extending outward from a second branch, the first plurality of comb fingers laterally interleaved between the second plurality of comb fingers; and the first plurality of comb fingers respectively including a weighted core material and one or more peripheral materials, the weighted core material having a larger density than the one or more peripheral materials. In some embodiments, the one or more peripheral materials include a core material arranged along both a horizontally extending surface and a vertically extending surface of the weighted core material. In some embodiments, a ratio of a cross-sectional area of the one or more peripheral materials to a cross-sectional area of the weighted core material within respective ones of the first plurality of comb fingers is in a range of between approximately 1:2 and approximately 1:4. In some embodiments, the one or more peripheral materials include a core material, the core material and the weighted core material having maximum widths that are substantially equal. In some embodiments, the one or more peripheral materials include a core material, the core material continuously extending in a closed loop around the weighted core material in a cross-sectional view. In some embodiments, the one or more peripheral materials include a core material; and a dielectric cover continuously extending in a closed loop around the weighted core material and the core material in a cross-sectional view. In some embodiments, the one or more peripheral materials include a semiconductor material and the weighted core material include a metal. In some embodiments, the first plurality of comb fingers respectively have a tapered width that decreases away from the first branch; and the weighted core material has a tapered width that decreases away from the first branch. In some embodiments, the first plurality of comb fingers respectively have a width and are laterally separated from one another by a first distance; and a ratio of the width to the first distance is less than or equal to approximately 2:1. In some embodiments, the first comb structure is part of an anchor having a first plurality of branches extending outward from a central region of the anchor, the first plurality of branches including the first branch; the second comb structure is part of a proof mass having a second plurality of branches, the second plurality of branches including the second branch; and one or more cantilevers are coupled between the proof mass and a frame, the frame wrapping around the proof mass.

In other embodiments, the present disclosure relates to a MEMS structure. The MEMS structure includes a first comb structure having a first plurality of comb fingers arranged within a cavity in a substrate, the first plurality of comb fingers being spaced apart from one another by the cavity; the first plurality of comb fingers respectively including a core material, a weighted core material vertically contacting the core material, and a dielectric cover wrapping around the core material and the weighted core material. In some embodiments, the weighted core material has a larger density than the core material. In some embodiments, a ratio of a density of the weighted core material to a density of the core material is greater than approximately 5:1. In some embodiments, the core material includes polysilicon and the weighted core material includes tungsten. In some embodiments, the MEMS structure further includes a second comb structure having a second plurality of comb fingers arranged within the cavity, the first plurality of comb fingers being laterally interleaved between adjacent ones of the second plurality of comb fingers. In some embodiments, the MEMS structure further includes a base substrate, the first comb structure being coupled to the base substrate by one or more first bonding structures arranged between an upper surface of the base substrate and a lower surface of the first comb structure; a mid-frame coupled to second comb structure; and an outer frame coupled to the mid frame by one or more conductive connectors and further coupled to the base substrate by one or more second bonding structures arranged between the upper surface of the base substrate and a lower surface of the outer frame. In some embodiments, the MEMS structure further includes an image sensor integrated chip coupled to an upper surface of the mid-frame that faces away from the base substrate.

In yet other embodiments, the present disclosure relates to a method. The method includes forming a plurality of trenches within a comb region of a substrate; forming a plurality of comb fingers within the plurality of trenches, the plurality of comb fingers respectively having a core material and a weighted core material, the weighted core material having a larger density than the core material; and removing parts of the substrate from between the plurality of comb fingers. In some embodiments, the plurality of comb fingers respectively include a dielectric cover wrapping around the core material and the weighted core material. In some embodiments, the core material includes a semiconductor material and the weighted core material includes a metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A MEMS (Microelectromechanical systems) structure, comprising:
a first comb structure comprising a first plurality of comb fingers extending outward from a first branch;
a second comb structure comprising a second plurality of comb fingers extending outward from a second branch, the first plurality of comb fingers laterally interleaved between the second plurality of comb fingers; and
wherein the first plurality of comb fingers respectively comprise a weighted core material and one or more peripheral materials, the weighted core material having a larger density than the one or more peripheral materials.

2. The MEMS structure of claim 1, wherein the one or more peripheral materials include a core material arranged along both a horizontally extending surface and a vertically extending surface of the weighted core material.

3. The MEMS structure of claim 1, wherein a ratio of a cross-sectional area of the one or more peripheral materials to a cross-sectional area of the weighted core material within respective ones of the first plurality of comb fingers is in a range of between approximately 1:2 and approximately 1:4.

4. The MEMS structure of claim 1, wherein the one or more peripheral materials include a core material, the core material and the weighted core material having maximum widths that are substantially equal.

5. The MEMS structure of claim 1, wherein the one or more peripheral materials include a core material, the core material continuously extending in a closed loop around the weighted core material in a cross-sectional view.

6. The MEMS structure of claim 1, wherein the one or more peripheral materials comprise:
a core material; and
a dielectric cover continuously extending in a closed loop around the weighted core material and the core material in a cross-sectional view.

7. The MEMS structure of claim 1, wherein the one or more peripheral materials comprise a semiconductor material and the weighted core material comprises a metal.

8. The MEMS structure of claim 1,
wherein the first plurality of comb fingers respectively have a tapered width that decreases away from the first branch; and
wherein the weighted core material has a tapered width that decreases away from the first branch.

9. The MEMS structure of claim 1,
wherein the first plurality of comb fingers respectively have a width and are laterally separated from one another by a first distance; and
wherein a ratio of the width to the first distance is less than or equal to approximately 2:1.

10. The MEMS structure of claim 1,
wherein the first comb structure is part of an anchor comprising a first plurality of branches extending outward from a central region of the anchor, the first plurality of branches including the first branch;
wherein the second comb structure is part of a proof mass comprising a second plurality of branches, the second plurality of branches including the second branch; and
wherein one or more cantilevers are coupled between the proof mass and a frame, the frame wrapping around the proof mass.

11. A MEMS structure, comprising:
a first comb structure comprising a first plurality of comb fingers arranged within a cavity in a substrate, the first plurality of comb fingers being spaced apart from one another by the cavity;
wherein the first plurality of comb fingers respectively comprise:
a core material;
a weighted core material vertically contacting the core material; and
a dielectric cover wrapping around the core material and the weighted core material.

12. The MEMS structure of claim 11, wherein the weighted core material has a larger density than the core material.

13. The MEMS structure of claim 11, wherein a ratio of a density of the weighted core material to a density of the core material is greater than approximately 5:1.

14. The MEMS structure of claim 11, wherein the core material comprises polysilicon and the weighted core material comprises tungsten.

15. The MEMS structure of claim 11, further comprising:
a second comb structure comprising a second plurality of comb fingers arranged within the cavity, the first plurality of comb fingers being laterally interleaved between adjacent ones of the second plurality of comb fingers.

16. The MEMS structure of claim 15, further comprising:
a base substrate, wherein the first comb structure is coupled to the base substrate by one or more first bonding structures arranged between an upper surface of the base substrate and a lower surface of the first comb structure;
a mid-frame coupled to second comb structure; and
an outer frame coupled to the mid frame by one or more conductive connectors and further coupled to the base substrate by one or more second bonding structures arranged between the upper surface of the base substrate and a lower surface of the outer frame.

17. The MEMS structure of claim 16, further comprising:
an image sensor integrated chip coupled to an upper surface of the mid-frame that faces away from the base substrate.

18. A method of forming a MEMS structure, comprising:
forming a plurality of trenches within a comb region of a substrate;
forming a plurality of comb fingers within the plurality of trenches, wherein the plurality of comb fingers respectively comprise a core material and a weighted core material, the weighted core material having a larger density than the core material; and
removing parts of the substrate from between the plurality of comb fingers.

19. The method of claim 18, wherein the plurality of comb fingers respectively comprise a dielectric cover wrapping around the core material and the weighted core material.

20. The method of claim 18, wherein the core material comprises a semiconductor material and the weighted core material comprises a metal.
